(19) United States
(12) Patent Application Publication
(10) Pub. No.: US 2011/0073933 A1
(43) Pub. Date: Mar. 31, 2011

(54) SEMICONDUCTOR DEVICE AND METHOD OF MANUFACTURING THE SAME

(75) Inventor: Norihisa Arai, Saitama-ken (JP)

(73) Assignee: KABUSHIKI KAISHA TOSHIBA, Tokyo (JP)

(21) Appl. No.: 12/894,466

(22) Filed: Sep. 30, 2010

(30) Foreign Application Priority Data
Sep. 30, 2009 (JP) 2009-228921

(51) Int. Cl. H01L 29/788; H01L 21/28

(52) U.S. Cl. 257/324; 438/257; 257/E29.3; 257/E21.158

(57) ABSTRACT

A semiconductor memory device includes: a semiconductor substrate; a first device-isolation insulation film that divides the semiconductor substrate at a first transistor region into first device regions; a second device-isolation insulation film that divides the semiconductor substrate at a second transistor region into second device regions; a plurality of first transistors formed in the first transistor region; a plurality of second transistors formed in the second transistor region; and an anti-inversion diffusion layer formed under the first device-isolation insulation film. Each of the first and second transistors includes, respectively: a first and second gate insulation film provided respectively on the first and second device regions; a first and second gate electrode provided respectively on the first and second gate insulation films; and a first and second diffusion layer formed respectively on a surface of the semiconductor substrate so as to sandwich the first and second gate electrodes.

### CROSS-REFERENCE TO RELATED APPLICATIONS

This application is based upon and claims the benefit of priority from the prior Japanese Patent Application No. 2009-228921, filed Sep. 30, 2009, the entire contents of which are incorporated herein by reference.

### FIELD

Exemplary embodiments herein relate to a semiconductor device and a method of manufacturing the same, and specifically to a semiconductor device including a high-voltage (HV) transistor region located in a peripheral circuit portion, and a device-isolation insulation film of the HV transistor includes a first portion and a second portion whose bottom surface is located at a deeper level than that of the first portion.

### BACKGROUND

NAND flash memories are an example of nonvolatile semiconductor memory devices on which data is electrically rewritable (write and erase). In a flash memory of this kind, plural transistor circuits are arranged around a memory-cell portion (peripheral circuit portion). The peripheral circuit portion of the flash memory is classified roughly into a LV transistor region and a HV transistor region.

A voltage of 20V or higher is applied to the HV transistor. For this reason, a breakdown voltage of a device-isolation insulation film that isolates HV transistors from each other is sufficiently high. That is, the device-isolation insulation film between the HV transistors needs to have a sufficiently large width.

In addition, in a case the threshold voltage of the HV transistor increases due to the back-bias effect, the device's breakdown voltage increases and an area of the booster circuit increases. As a result, the semiconductor device is made larger in size, which results in an increase in the manufacturing cost.

As a method to address this problem, it has already been proposed that the STI is shaped to have a downwardly protruding portion. To enhance the device isolation breakdown voltage between HV transistors, an anti-inversion diffusion layer is sometimes formed under the device-isolation insulation film. If a high voltage is applied to the gate electrodes of the HV transistors, the depletion layer of the channel region extends to the anti-inversion diffusion layer under the device-isolation insulation film. As a result, the threshold voltage of the HV transistors is increased.

### BRIEF DESCRIPTION OF THE DRAWINGS

FIG. 1(a) to FIG. 1(c) are plan views illustrating an exemplary configuration of a semiconductor device (NAND flash memory) according to a first exemplary Embodiment 1.

FIG. 2(a) is a sectional view taken along the line A-A of FIG. 1(a). FIG. 2(b) is a sectional view taken along the line B-B of FIG. 1(a).

FIG. 3(a) is a sectional view taken along the line C-C of FIG. 1(b). FIG. 3(b) is a sectional view taken along the line D-D of FIG. 1(b).

FIG. 4 is a sectional view taken along the line E-E of FIG. 1(c).

FIG. 5(a) to FIG. 5(e) are sectional views to describe a manufacturing process of the NAND flash memory according to the first exemplary Embodiment 1. FIG. 5(a) is a sectional view taken along the line A-A of FIG. 1(a). FIG. 5(b) is a sectional view taken along the line B-B of FIG. 1(a). FIG. 5(c) is a sectional view taken along the line C-C of FIG. 1(b). FIG. 5(d) is a sectional view taken along the line D-D of FIG. 1(b). FIG. 5(e) is a sectional view taken along the line E-E of FIG. 1(c).

FIG. 6(a) to FIG. 6(e) are sectional views to describe the manufacturing process of the NAND flash memory according to the first exemplary Embodiment 1, and are sectional views that follow the ones shown in FIG. 5(a) to FIG. 5(e).

FIG. 7(a) to FIG. 7(e) are sectional views to describe the manufacturing process of the NAND flash memory according to the first exemplary Embodiment 1, and are sectional views that follow the ones shown in FIG. 6(a) to FIG. 6(e).

FIG. 8(a) to FIG. 8(e) are sectional views to describe the manufacturing process of the NAND flash memory according to the first exemplary Embodiment 1, and are sectional views that follow the ones shown in FIG. 7(a) to FIG. 7(e).

FIG. 9(a) to FIG. 9(e) are sectional views to describe the manufacturing process of the NAND flash memory according to the first exemplary Embodiment 1, and are sectional views that follow the ones shown in FIG. 8(a) to FIG. 8(e).

FIG. 10(a) to FIG. 10(e) are sectional views to describe the manufacturing process of the NAND flash memory according to the first exemplary Embodiment 1, and are sectional views that follow the ones shown in FIG. 9(a) to FIG. 9(e).

FIG. 11 is a sectional view to describe effects of the NAND flash memory according to the first exemplary Embodiment 1, and is a sectional view taken along the line A-A of FIG. 1(a).

FIG. 12(a) to FIG. 12(c) are plan views illustrating an exemplary configuration of a semiconductor device (NAND flash memory) according to a Modified Example 1 of the first exemplary Embodiment 1.

FIG. 13 is a sectional view of the NAND flash memory according to Modified Example 1 of the first exemplary Embodiment 1, and is a sectional view taken along the line A-A of FIG. 12(a).

FIGS. 14(a) to 14(e) are sectional views of a NAND flash memory according to Modified Example 2 of the first exemplary Embodiment 1. FIG. 14(a) is a sectional view taken along the line A-A of FIG. 1(a). FIG. 14(b) is a sectional view taken along the line B-B of FIG. 1(a). FIG. 14(c) is a sectional view taken along the line C-C of FIG. 1(b). FIG. 14(d) is a sectional view taken along the line D-D of FIG. 1(b). FIG. 14(e) is a sectional view taken along the line E-E of FIG. 1(c).

FIGS. 15(a) to 15(e) are sectional views to describe a manufacturing process of the NAND flash memory according to Modified Example 2 of the first exemplary Embodiment 1. FIG. 15(a) is a sectional view taken along the line A-A of FIG. 1(a). FIG. 15(b) is a sectional view taken along the line B-B of FIG. 1(a). FIG. 15(c) is a sectional view taken along the line C-C of FIG. 1(b). FIG. 15(d) is a sectional view taken along the line D-D of FIG. 1(b). FIG. 15(e) is a sectional view taken along the line E-E of FIG. 1(c).

FIGS. 16(a) to 16(e) are sectional views to describe a manufacturing process of the NAND flash memory according to Modified Example 2 of the first exemplary Embodiment 1, and are sectional views that follow the ones shown in FIG. 15(a) to FIG. 15(e).

FIGS. 17(a) to 17(e) are sectional views to describe the manufacturing process of the NAND flash memory according to Modified Example 2 of the first exemplary Embodiment 1, and are sectional views that follow the ones shown in FIGS. 16(a) to 16(e).

FIGS. 18(a) and 18(b) are sectional views of the NAND flash memory according to a second exemplary Embodiment 2. FIG. 18(a) is a sectional view taken along the line A-A of FIG. 1(a). FIG. 18(b) is a sectional view taken along the line B-B of FIG. 1(a).

FIGS. 19(a) and 19(b) are sectional views of the NAND flash memory according to the second exemplary Embodiment 2. FIG. 19(a) is a sectional view taken along a line corresponding to the line C-C of FIG. 1(b). FIG. 19(b) is a sectional view taken along a line corresponding to the line D-D of FIG. 1(b).

FIG. 20 is a sectional view of the NAND flash memory according to the second exemplary Embodiment 2, and is a sectional view taken along a line corresponding to the line E-E of FIG. 1(c).

FIGS. 21(a) to 21(e) are sectional views to describe a manufacturing process of the NAND flash memory according to the second exemplary Embodiment 2. FIG. 21(a) is a sectional view taken along the line A-A of FIG. 1(a). FIG. 21(b) is a sectional view taken along the line B-B of FIG. 1(a). FIG. 21(c) is a sectional view taken along the line C-C of FIG. 1(b). FIG. 21(d) is a sectional view taken along the line D-D of FIG. 1(b). FIG. 21(e) is a sectional view taken along the line E-E of FIG. 1(c).

FIGS. 22(a) to 22(e) are sectional views to describe the manufacturing process of the NAND flash memory according to the second exemplary Embodiment 2, and are sectional views that follow the ones shown in FIGS. 21(a) to 21(e).

FIGS. 23(a) to 23(e) are sectional views to describe the manufacturing process of the NAND flash memory according to the second exemplary Embodiment 2, and are sectional views that follow the ones shown in FIGS. 22(a) to 22(e).

FIGS. 24(a) to 24(e) are sectional views to describe the manufacturing process of the NAND flash memory according to the second exemplary Embodiment 2, and are sectional views that follow the ones shown in FIGS. 23(a) to 23(a).

FIGS. 25(a) to 25(e) are sectional views obtained by applying Modified Example 2 of the first exemplary Embodiment 1 to the second exemplary Embodiment 2. FIG. 25(a) is a sectional view taken along the line A-A of FIG. 1(a). FIG. 25(b) is a sectional view taken along the line B-B of FIG. 1(a). FIG. 25(c) is a sectional view taken along the line C-C of FIG. 1(b). FIG. 25(d) is a sectional view taken along the line D-D of FIG. 1(b). FIG. 25(e) is a sectional view taken along the line E-E of FIG. 1(c).

### DETAILED DESCRIPTION

Exemplary embodiments will be described below by referring to the drawings. Note that the drawings are schematic, and that the dimensions and the proportions in each drawing are different from their respective counterparts in the actual semiconductor device. In addition, the dimensions and proportions in one drawing may be different from their respective counterparts in another drawing. In addition, the embodiments to be described below illustrate devices and methods that may be employed to implement the technical idea of aspects of the invention. Accordingly, the shapes, the structures, the arrangement, or the like of the constituent parts does not limit the technical idea. The technical idea may be modified in various ways.

A semiconductor memory device according to an exemplary aspect includes: a semiconductor substrate; a first device-isolation insulation film that divides the semiconductor substrate at a first transistor region into first device regions; a second device-isolation insulation film that divides the semiconductor substrate at a second transistor region into second device regions; a plurality of first transistors formed in the first transistor region; a plurality of second transistors formed in the second transistor region; and an anti-inversion diffusion layer formed under the first device-isolation insulation film, wherein each of the first transistors includes: a first gate insulation film provided on the first device region; a first gate electrode provided on the first gate insulation film and extending on the first device-isolation insulation film; and a first diffusion layer formed on a surface of the semiconductor substrate so as to sandwich the first gate electrode, each of the second transistors includes: a second gate insulation film provided on the second device region and having a smaller film thickness than the first gate insulation film; a second gate electrode provided on the second gate insulation film; and a second diffusion layer formed on the surface of the semiconductor substrate so as to sandwich the second gate electrode, the first device-isolation insulation film includes: a first region that is adjacent to the first device region; and a second region whose bottom portion is located at a deeper level than a bottom portion of the first region, and the anti-inversion diffusion layer is formed under the second region of the first device-isolation insulation film.

A method of manufacturing a semiconductor device according to an exemplary aspect includes: forming a first gate insulation film on a semiconductor substrate in a first region of a first transistor region; forming a second gate insulation film on the semiconductor substrate in a second region of the first transistor region and in a second transistor region, the second gate insulation film having a smaller film thickness than the first gate insulation film, and the second region surrounding the first region; etching the first gate insulation film, the second gate insulation film, and the semiconductor substrate, and thereby forming a first trench in the first region of the first transistor region, forming a deeper second trench than the first trench in the second region of the first transistor region, and forming a third trench in the second transistor region; filling the first trench and the second trench with an insulation film, thereby forming a first device-isolation insulation film; and filling the third trench with an insulation film, thereby forming a second device-isolation insulation film; forming an anti-inversion diffusion layer under the second trench of the first device-isolation insulation film; forming a first gate electrode on the first gate insulation film of the first transistor region, and forming a second gate electrode on the second gate insulation film of the second transistor region; and forming a diffusion layer by using the first gate electrode and the second gate electrode as a mask.

### Exemplary First Embodiment 1

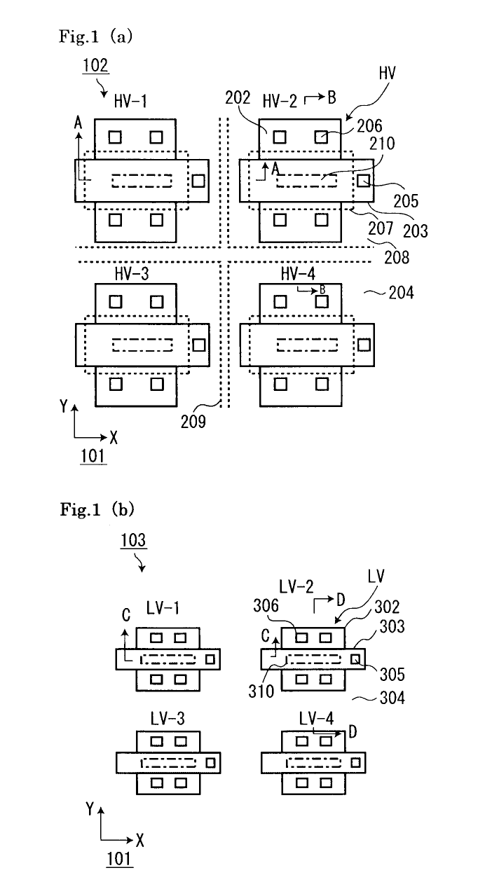

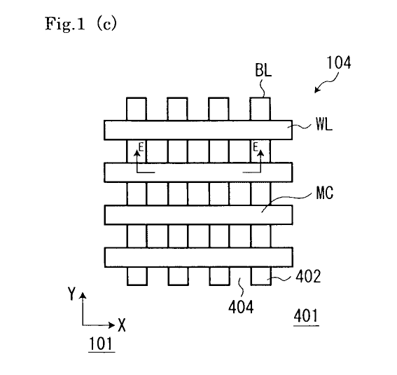

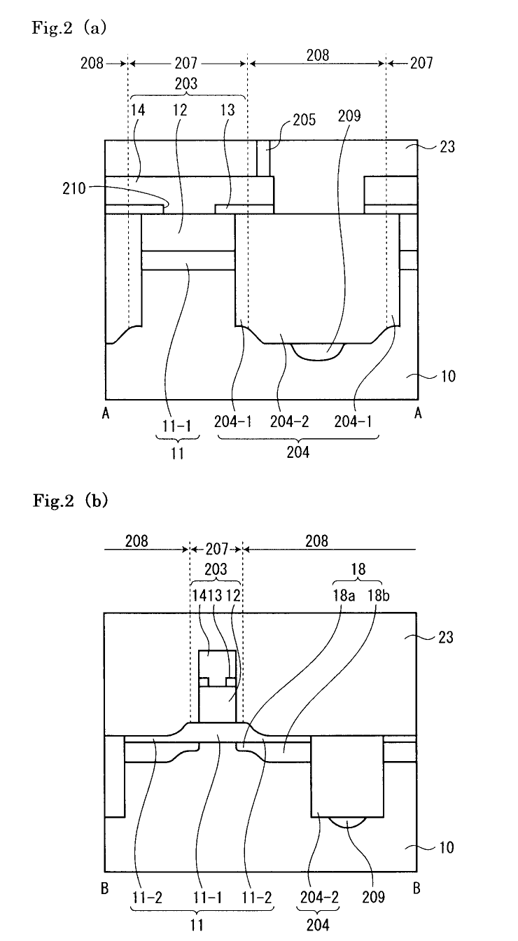

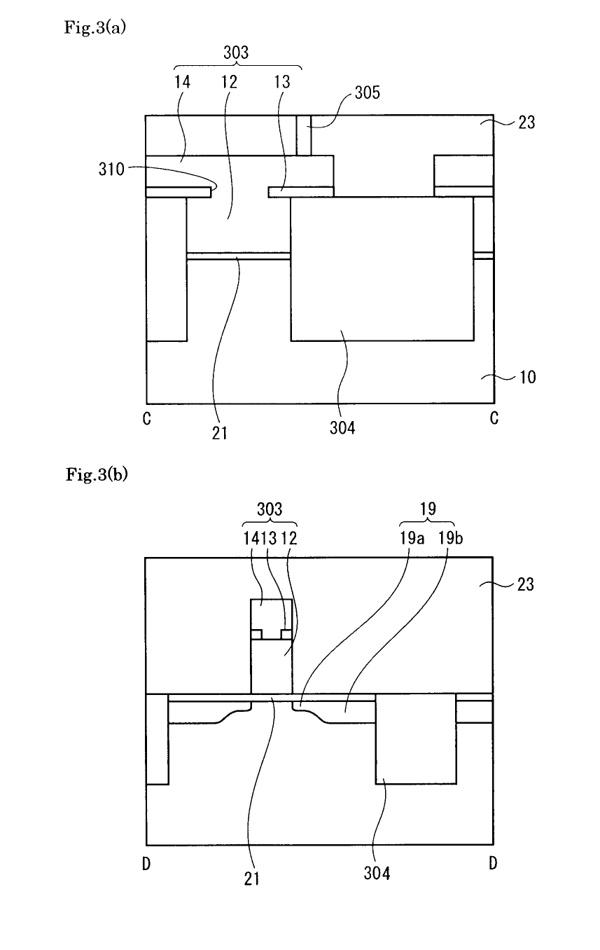

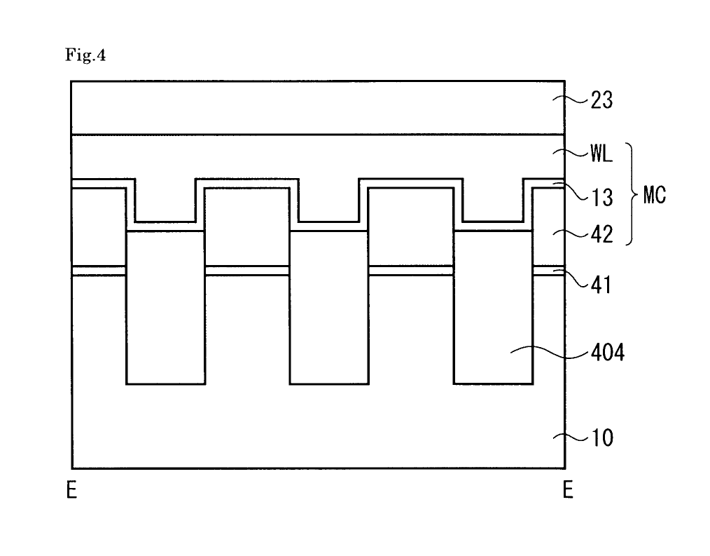

FIG. 1 to FIG. 4 shows an exemplary configuration of a semiconductor device according to a first exemplary Embodiment 1. This embodiment is described by taking a NAND flash memory—a kind of nonvolatile semiconductor memory device—as an example of semiconductor devices in which the device-isolation structure in the LV transistor region differs from the device-isolation structure in the HV transistor region. FIG. 1(a) is a plan view illustrating the HV transistor region of the peripheral circuit portion in the semiconductor device. FIG. 1(b) is a plan view illustrating the LV transistor region of the peripheral circuit portion in the semiconductor device. FIG. 1(c) is a plan view of a memory-cell portion. FIG. 2(a) is a sectional view of the HV transistor region taken along the line A-A (in the X-direction) of FIG. 1(a). FIG. 2(b) is a sectional view of the HV transistor region taken along the line B-B (in the Y-direction) of FIG. 1(a). FIG. 3(a) is a sectional view of the LV transistor region taken along the line C-C (in the X-direction) of FIG. 1(b). FIG. 3(b) is a sectional view of the LV transistor region taken along the line D-D (in the Y-direction) of FIG. 1(b). FIG. 4 is a sectional view of a memory-cell portion taken along the line E-E (in the X-direction) of FIG. 1(c).

The X-direction in FIG. 1 will be referred also to as the channel-width direction, or as the word-line direction. The Y-direction in FIG. 1 will be referred also to as the channel-length direction, or as the bit-line direction.

As FIG. 1(a) shows, plural HV transistors (MOS transistors) HV are formed in a HV transistor region 102 located in a peripheral circuit portion 101 of the semiconductor device. In this embodiment, the HV transistor on the upper left-hand side is denoted by HV-1, the HV transistor on the upper right-hand side is denoted by HV-2, the HV transistor on the lower left-hand side is denoted by HV-3, and the HV transistor on the lower right-hand side is denoted by HV-4.

Each of the HV transistors HV includes a device region 202 and a gate electrode 203 that extends in the X-direction in FIG. 1(a). Since each device region 202 is surrounded by a device-isolation insulation film (STI) 204, the HV transistors HV-1 to HV-4 are electrically isolated from one another. Note that, sets of the HV transistors HV are usually arranged in a random way within the HV transistor region 102.

A gate electrode contact 205 is provided in each of the gate electrodes 203, and the gate electrode contact 205 is connected to an upper-layer wiring (not illustrated). In addition, diffusion layer contacts 206 are provided in each of the device regions 202. These diffusion layer contacts 206 are connected to an upper-layer wiring (not illustrated).

A first region 207 is provided so as to surround the intersecting area of each gate electrode 203 and device region 202. Each of the first regions 207 is offsetted from the intersecting area of the gate electrode 203 and the device region 202, and thus extends in the Y-direction in FIG. 1(a) to the device region 202. In addition, each first region 207 is offsetted from the corresponding device region 202, and thus extends in the X-direction in FIG. 1(a) to the device-isolation insulation film 204. Note that, in the HV transistor region 102, the regions other than the first regions 207 are referred to as second regions 208.

An anti-inversion diffusion layer 209 is provided on the device-isolation insulation film 204 provided between the HV transistors HV-1 to HV-4. The anti-inversion diffusion layer 209 is formed approximately in the central area between each two HV transistors HV and within the second region 208. Note that the anti-inversion diffusion layer 209 of this embodiment forms a cross shape, but the anti-inversion diffusion layer 209 may be formed only between the gate electrodes 203 of each two HV transistors HV. In addition, the anti-inversion diffusion layer 209 may be formed only between the device regions 202 of each two HV transistors HV.

FIG. 2(a) shows a sectional view taken along the line A-A of FIG. 1(a).

As shown in FIG. 2(a), for example, the gate electrode 203 of each HV transistor HV is provided on a first gate insulation film 11-1 of a thickness of approximately 40 nm, which is formed on a p type (a first conductivity type) silicon (Si) substrate 10. The gate electrode 203 has a layered structure in which an inter-gate insulation film 13 and a second electrode film 14 are formed selectively on a first electrode film 12. Note that a metal salicide film (not shown) to reduce resistance may be formed over the second electrode film 14.

The first gate insulation film 11-1 is, for example, a silicon oxide film, silicon oxynitride film, or a laminate film including these two kinds of films. The first and the second electrode films 12 and 14 are made, for example, of polysilicon. The inter-gate insulation film 13 is, for example, an ONO film or an NONON film.

An opening is formed in the inter-gate insulation film 13 in a portion corresponding to an electrode-connection portion 210 shown in FIG. 1(a), and thus the first electrode film 12 is connected to the second electrode film 14. Note that the second electrode film 14 may have a dual layer structure including: a lower-layer electrode film formed only on the inter-gate insulation film 13; and an upper-layer electrode film formed both on the lower-layer electrode film and in the opening.

The device-isolation insulation film 204 is provided to be in contact with the side surfaces of the first gate insulation films 11-1 and of the first electrode films 12. The device-isolation insulation film 204 is, for example, a silicon oxide film, a PSZ film, or a laminate film including these two kinds of films.

The device-isolation insulation film 204 includes first regions 204-1 and a second region 204-2 whose bottom portion is located at a deeper level than the bottom portion of the first region 204-1. In the X-direction, each of the first regions 204-1 is in contact with the side surfaces of the first gate insulation film 11-1 and of the first electrode film 12, and the second region 204-2 is sandwiched by the first regions 204-1. In addition, the first regions 204-1 are connected to the second region 204-2 so that the bottom portions of the regions 204-1 and 204-2 gradually change in level.

In addition, the first regions 204-1 are provided in portions that correspond to the first regions 207 in FIG. 1. The second region 204-2 is formed in a portion that corresponds to the second region 208 in FIG. 1. Accordingly, the first region 207 of the device-isolation insulation film 204 is adjacent to the device region 202. In addition, the first region 207 of the device-isolation insulation film 204 surrounds the side surfaces of the device region 202 right below the gate electrode 203 in the channel-width direction of the HV transistor HV.

In addition, a portion of the gate electrode 203 provided on the device-isolation insulation film 204 only includes the inter-gate insulation film 13 and the second electrode film 14. In addition the top surface of the device-isolation insulation film 204 is positioned at approximately the same level as the top surface of the first electrode film 12.

The gate electrode contact 205 is provided on a portion of the second electrode film 14 formed above the device-isolation insulation film 204. In addition, an interlayer insulation film 23 is formed to bury both the gate electrode 203 and the gate electrode contact 205.

The anti-inversion diffusion layer 209 is a P type (first conductivity type) impurity diffused layer region, and is formed only under the second region 204-2 of the device-isolation insulation film 204. Accordingly, the anti-inversion diffusion layer 209 is not formed under the first region 204-1 of the device-isolation insulation film 204. In addition, the top surface of the anti-inversion diffusion layer 209 is in contact with the bottom portion of the second region 204-2 of the device-isolation insulation film 204.

FIG. 2(b) shows a sectional view taken along the line B-B of FIG. 1(a). The first gate insulation film 11-1 and second gate insulation films 11-2 that are thinner than the first gate insulation film 11-1 are formed over a portion of the Si substrate 10 corresponding to the device region 202. The first gate insulation film 11-1 is provided in the first region 207, whereas the second gate insulation films 11-2 are formed in the second regions 208. Note that the first gate insulation film 11-1 and the second gate insulation films 11-2 may also be collectively referred to as a gate insulation film 11.

The film thickness of each second gate insulation film 11-2 is approximately 10 nm. The first gate insulation film 11-1 is provided so as to be sandwiched by the second gate insulation films 11-2 in the channel-length direction. The top surface of the first gate insulation film 11-1 is higher than the top surfaces of the second gate insulation films 11-2. The bottom surface of the first gate insulation film 1′-1 is located at approximately the same level as the bottom surfaces of the second gate insulation films 11-2. The gate electrode 203 is provided only on the first gate insulation film 11-1. The first gate insulation film 11-1 is connected to the second gate insulation films 11-2 so that the level of the top surface of the gate insulation film 11 changes gradually.

In the surface portion of the Si substrate 10, diffusion-layer regions 18a (n−) and diffusion-layer regions 18b (n+) whose impurity concentration is higher than the impurity concentration of the diffusion-layer regions 18a are formed so as to sandwich the gate electrode 203. The bottom portion of each diffusion-layer region 18a is located at a shallower position than the bottom portion of each diffusion-layer region 18b. Spacer films (not illustrated) are provided on the sidewalls of the gate electrode 203. With the spacer films, the diffusion-layer regions 18a and the diffusion-layer regions 18b may be formed in a self-aligned manner.

The device-isolation insulation films 204 are formed to be in contact with the diffusion-layer regions 18b. Each of these device-isolation insulation films 204 includes only the second region 204-2 in FIG. 2(b). The anti-inversion diffusion layer 209 is formed under the second region 204-2 of each device-isolation insulation film 204. The top surface of the anti-inversion diffusion layer 209 is in contact with the bottom portion of the second region 204-2 of the device-isolation insulation film 204.

In this sectional view, the top surface of the device-isolation insulation film 204 is located at the same height as the height of the top surface of each second gate insulation film 11-2. However, the top surface of the device-isolation insulation film 204 may be located at a height that is different from the height of the top surface of each second gate insulation film 11-2.

As FIG. 1(b) shows, plural LV transistors (MOS transistors) LV are formed in a LV transistor region 103 located in the peripheral circuit portion 101 of the semiconductor device. In this embodiment, the LV transistor on the upper left-hand side is denoted by LV-1, the LV transistor on the upper right-hand side is denoted by LV-2, the LV transistor on the lower left-hand side is denoted by LV-3, and the LV transistor on the lower right-hand side is denoted by LV-4.

Each of the LV transistors LV includes a device region 302 and a gate electrode 303 that extends in the X-direction in FIG. 1(b). Since each device region 302 is surrounded by a device-isolation insulation film (STI) 304, the LV transistors LV-1 to LV-4 are electrically isolated from one another. Note that, sets of the LV transistors LV-1 to LV-4 are usually arranged in a random way within the LV transistor region 103.

A gate electrode contact 305 is provided in each of the gate electrodes 303, and the gate electrode contact 305 is connected to an upper-layer wiring (not illustrated). In addition, diffusion layer contacts 306 are provided in each of the device regions 302. These diffusion layer contacts 306 are connected to an upper-layer wiring (not illustrated).

Unlike the case of the HV transistor region 102, an anti-inversion diffusion layer is not provided on the device-isolation insulation film 304 between the LV transistors LV. Each of the LV transistors LV is driven by a voltage of 5 V or lower, so that the device-isolation insulation film between the LV transistors LV has a smaller breakdown voltage than that of the HV transistors HV. Accordingly, the distance between each two LV transistors LV can be shortened, and thus the semiconductor device can be made smaller in size.

FIG. 3(a) shows a sectional view taken along the line C-C of FIG. 1(b).

As shown in FIG. 3(a), the gate electrode 303 of each LV transistor LV is, for example, provided on a third gate insulation film 21, which is formed on the P type (first conductivity type) silicon (Si) substrate 10. The third gate insulation film 21 is made of the same material as that of the second gate insulation film 11-2. In addition, the film thickness of the third gate insulation film 21 is substantially equal to the film thickness of the second gate insulation film 11-2. The top surface of the third gate insulation film 21 is located at substantially the same level as that of the top surface of the second gate insulation film 11-2. To put it differently, the position of the top surface of the Si substrate 10 in the HV transistor region 102 is the same as that of the top surface of the Si substrate 10 in the LV transistor region 103.

The gate electrode 303 has a layered structure in which the inter-gate insulation film 13 and the second electrode film 14 are provided selectively on the first electrode film 12. Note that a metal salicide film (not shown) to reduce resistance may be formed over the second electrode film 14.

An opening is formed in the inter-gate insulation film 13 in a portion corresponding to an electrode-connection portion 310 shown in FIG. 1(b), and thus the first electrode film 12 is connected to the second electrode film 14. Note that the second electrode film 14 may have a dual layer structure including: a lower-layer electrode film formed only on the inter-gate insulation film 13; and an upper-layer electrode film formed both on the lower-layer electrode film and in the opening.

Each of the device-isolation insulation film 304 is formed to be in contact with the side surfaces of the third gate insulation films 21 and of the first electrode films 12. The device-isolation insulation film 304 is made of the same material as that of the device-isolation insulation film 204 in HV transistor region 102.

The bottom surface of each device-isolation insulation film 304 is substantially at the same position as that of the bottom surface of the second region 204-2 of the device-isolation insulation film 204 in the HV transistor region 102.

In addition, in a portion of the gate electrode 303 provided on the device-isolation insulation film 304, only the inter-gate insulation film 13 and the second electrode film 14 are formed on and above the device-isolation insulation film 304. In addition the top surface of the device-isolation insulation film 304 is positioned at approximately the same level as the top surface of the first electrode film 12.

The gate electrode contact 305 is provided on a portion of the second electrode film 14 that is above the device-isolation insulation film 304. In addition, an interlayer insulation film 23 is formed so as to bury both the gate electrode 303 and the gate electrode contact 305.

FIG. 3(b) shows a sectional view taken along the line D-D of FIG. 1(b). The third gate insulation film 21 is formed over a portion of the Si substrate 10 corresponding to the device region 302. In the surface portion of the Si substrate 10, diffusion-layer regions 19a (n−) and diffusion-layer regions 19b (n+) whose impurity concentration is higher than the impurity concentration of the diffusion-layer regions 19a are formed so as to sandwich the gate electrode 303. In addition, the bottom portion of each diffusion-layer region 19a is located at a shallower position than the bottom portion of each diffusion-layer region 19b. Spacer films (not illustrated) are provided on the sidewalls of the gate electrode 303. With the spacer films, the diffusion-layer regions 19a and the diffusion-layer regions 19b may be formed in a self-aligned manner.

The device-isolation insulation films 304 are formed to be in contact with the diffusion-layer regions 19b. In this sectional view, the top surface of the device-isolation insulation film 304 has the same height as that of the top surface of the third gate insulation film 21. The top surface of each device-isolation insulation film 304 may have a height that is different from that of the top surface of the third gate.

As FIG. 1(c) shows, plural memory cells MC are formed in a cell region (cell array) 104 located in a memory-cell portion 401 of the semiconductor device. The memory cells MC are arranged respectively at the intersecting portions of word lines (control gate electrode) WL that extend in the X-direction and bit lines BL that extend in the Y-direction. Each memory cell MC includes a gate electrode 403 that has a laminate gate electrode structure. The gate electrode 403 includes a control gate electrode and a floating gate electrode. The memory cell MC performs the rewriting (writing and erasing) of data by, for example, using the FN tunnel current to pour charges (electron) into, or take them out of, the floating gate electrode. In general, the state where electrons are in the floating gate electrode is the writing of a value “0”, while the state where electrons are not in the floating gate electrode is the writing of a value “1”. Floating gate electrodes are provided corresponding respectively to device regions 402. The word lines WL are arranged across plural device regions 402. Each device region 402 is surrounded by device-isolation insulation films (STI) 404 that are each formed by filling an insulation film.

FIG. 4 shows a sectional view taken along the line E-E of FIG. 1(c). As FIG. 4 shows, the memory cells MC are formed on a tunnel insulation film 41 that is provided on the P type (first conductivity type) Si (silicon) substrate 10. The tunnel insulation film 41 is made of the same material as that of the second gate insulation film 11-2 and has substantially the same film thickness as that of the second gate insulation film 11-2. In addition, the top surface of the tunnel insulation film 41 is positioned at substantially the same level as that of the top surface of the second gate insulation film 11-2. To put it differently, top surfaces of the Si substrate 10 of the HV transistor region 102 and the cell region 104 are substantially on the same level.

Each memory cell MC includes a floating gate electrode 42 provided on the tunnel insulation film 41, the inter-gate insulation film 13 provided on a top surface and upper side surfaces of the floating gate electrode 42, and a control gate electrode WL provided on the inter-gate insulation film 13. A metal salicide film (not shown) to reduce the resistance may be formed both on the control gate electrode WL.

The device-isolation insulation films 404 are provided in contact with the side surfaces of the tunnel insulation films 41 and of the floating gate electrodes 42. The device-isolation insulation film 404 is made of the same material as that of the device-isolation insulation film 204 of the HV transistor region 102. The top surfaces of the device-isolation insulation film 404 are lower than the top surfaces of the floating gate electrodes 42. The inter-gate insulation film 13 is in contact with the top surfaces of the device-isolation insulation films 404, and is continuously formed to cover the memory cells MC that are adjacent to one another in the X-direction. Likewise, the control gate electrode WL is connected commonly to the memory cells MC that are adjacent to one another in the X-direction.

The bottom surfaces of the device-isolation insulation films 404 are positioned at the same level as the bottom of the surfaces of the second regions 204-2 of the device-isolation insulation films 204 located in the HV transistor region 102. In addition, the interlayer insulation film 23 is provided to cover the memory cells MC.

In a NAND flash memory, a predetermined number of memory cells MC are connected in series to one another. An end of memory cells in each of the series is connected to the bit line BL through a drain-side select transistor, whereas the other end thereof is connected to the source line through a source-side select transistor.

The top surfaces of the gate electrodes 203 of the HV transistors HV, the top surfaces of the gate electrodes 303 of the LV transistors LV, and the top surfaces of the word lines WL have substantially the same heights.

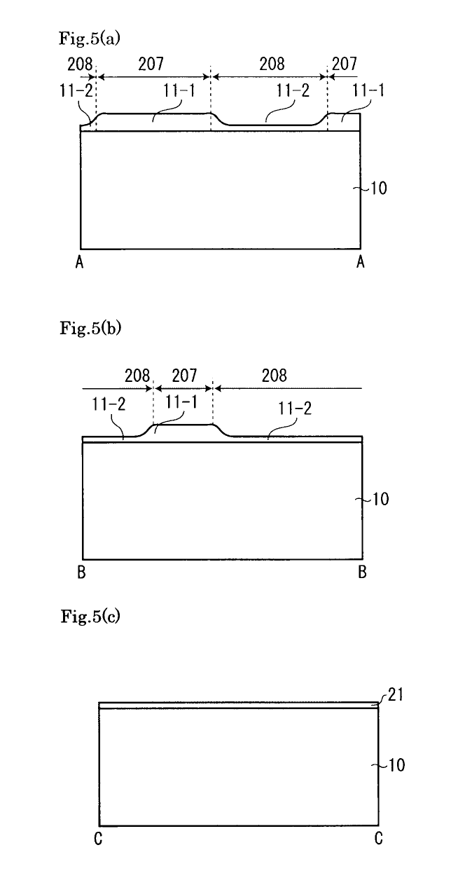

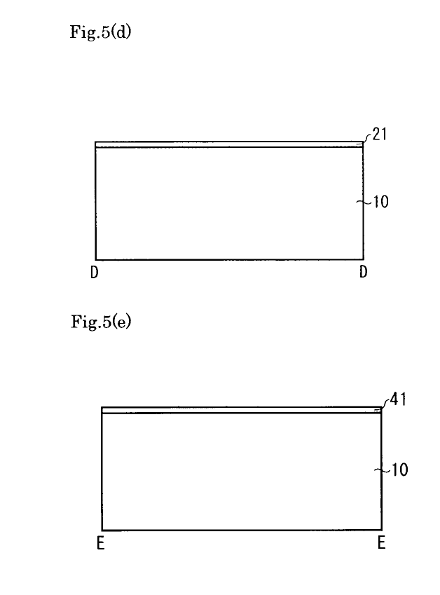

A method of manufacturing the above-described NAND flash memory is described by referring to FIGS. 5 to 10. Note that FIGS. 5(a) to 10(a) show sectional views corresponding to FIG. 2(a), FIGS. 5(b) to 10(b) show sectional views corresponding to FIG. 2(b), FIGS. 5(c) to 10(c) show sectional views corresponding to FIG. 3(a), FIGS. 5(d) to 10(d) show sectional views corresponding to FIG. 3(b), and FIGS. 5(e) to 10(e) show sectional views corresponding to FIG. 4.

P-well regions (not illustrated) are formed in surface portions of the Si substrate 10 that correspond to the LV transistor region 103 and to the cell region 104. If the LV transistors LV are P type transistors, an N-well region (not illustrated) is formed in the Si substrate 10 corresponding to the LV transistor region 103. In addition, in the cell region 104, an N-well region (not illustrated) is formed under the P-well region.

As FIGS. 5(a) to 5(e) show, a first insulation film that is to be the gate insulation films of the HV transistors HV is deposited on the entire surface of the Si substrate 10 so as to have, for example, an approximately 40-nm thickness.

By the lithograph technique and the etching technique, the first insulation film of the LV transistor region 103, the first insulation film of the cell region 104, and the first insulation film of the second region 208 of the HV transistor region 102 are removed.

By the CVD method, a second insulation film is formed on the top surface of the Si substrate 10 so as to have, for example, an approximately 5 to 10-nm thickness. The second insulation film that is to be the third gate insulation films 21 of the LV transistors LV and to be the tunnel insulation films 41 of the memory cells MC is formed so as to have an approximately 5 to 10-nm thickness. At the same time, the second insulation film is formed also in the HV transistor region 102. The second insulation film (second gate insulation film 11-2) is formed in the second region 208, and a laminate film (first gate insulation film 11-1) including both the first insulation film and the second insulation film is formed in the first region 207 (formation of gate insulation film).

Around the border between the first region 207 and each second region 208 of the HV transistor region 102, a level difference is formed corresponding to the difference between the film thickness of the first gate insulation film 11-1 and the film thickness of the second gate insulation film 11-2. The level difference is so formed that the top surface of the first gate insulation film 11-1 gradually lowers toward the second region 208 to be finally connected to the top surface of the second gate insulation film 11-2.

The top surface of the Si substrate in the HV transistor region 102, the top surface of the Si substrate in the LV transistor region 103, and the top surface of the Si substrate in the cell region 104 are approximately at the same level. Accordingly, the top surfaces of the second gate insulation films 11-2 in the HV transistor region 102, the top surfaces of the gate insulation films 21 of the LV transistors LV, and the top surfaces of tunnel insulation films 41 of the memory cells MC are approximately at the same level.

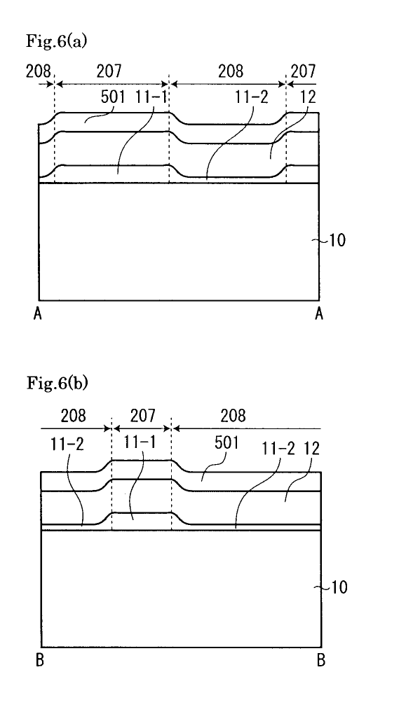

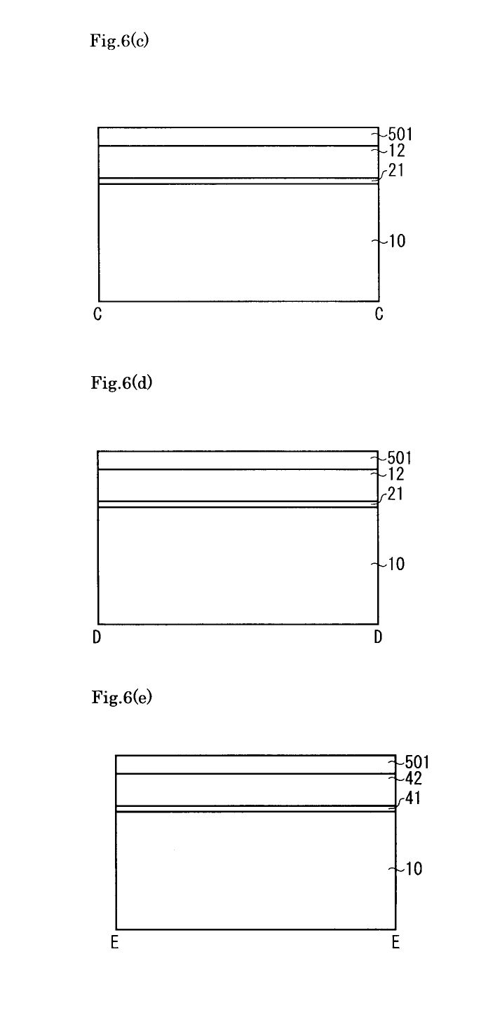

As FIGS. 6(a) to 6(e) show, the first electrode film 12 is deposited on the entire surface so as to form both the floating gate electrodes 42 of the memory cells MC and the first electrode films 12. A first mask material 501 to form device-isolation insulation films 204, 304, and 404 is deposited on the first electrode film 12 so as to have a certain film thickness. As a result, in the HV transistor region 102, the top surface of the first mask material 501 has a shape that traces the top surfaces of the first and the second gate insulation films 11-1 and 11-2.

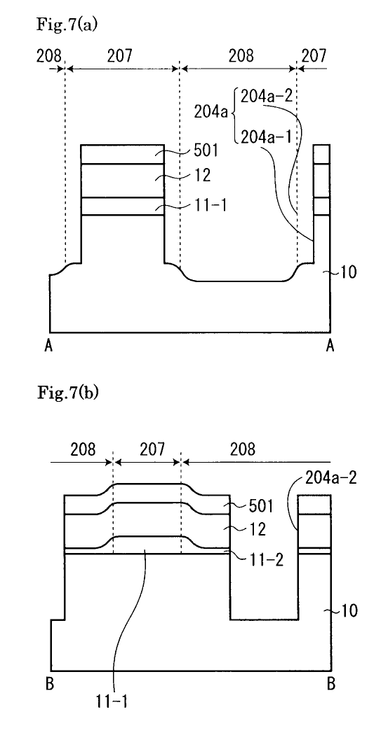

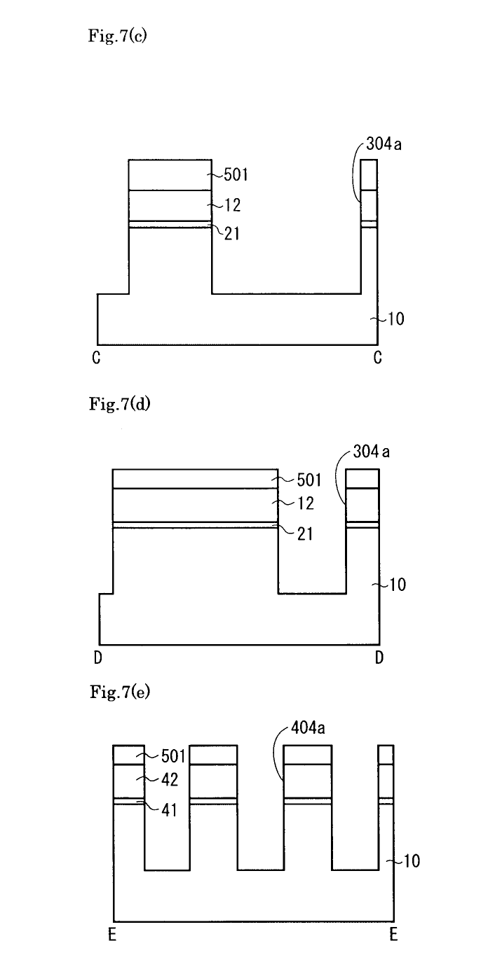

As FIGS. 7(a) to 7(e) show, a resist mask having openings at the regions where device-isolation insulation films 204, 304, and 404 are to be formed is formed by, for example, lithography. Device-isolation trenches 204a, 304a, and 404a where the device-isolation insulation films 204, 304, and 404 are to be formed, respectively, is formed by, for example, an etching technique at a single process (device-isolation trench forming process). The top surface of the first mask material 501 in the HV transistor region 102 is formed so that the portions of the top surfaces above the first gate insulation films 11-1 are lower than the portions thereof above the second gate insulation films 11-2. In addition, in the HV transistor region 102, the laminate structure of the first region 207 and the laminate structure of the second region 208 are basically the same except that the film thicknesses of the first and the second gate insulation films 11-1 and 11-2 are different.

By the single etching of the layered structure of the HV transistor region 102, a second trench 204a-2 is formed in the second region 208 of each device isolation trench 204a in the HV transistor region 102, and first trenches 204a-1 each of which has a shallower bottom surface than the bottom surface of the second trench 204a-2 is formed in the first regions 207. Since the film thickness of the first gate insulation film 11-1 in the first region 207 is larger than the film thickness of the second gate insulation film 11-2, the depth measured from the surface of the Si substrate 10 is larger in the second trench 204a-2 than in the first trench 204a-1 formed in the first region 207.

The difference in level between the bottom surface of the first trench 204a-1 and the bottom surface of the second trench 204a-2 can be adjusted by changing the etching selectivity of each of the gate insulation film 11 and the Si substrate 10. For example, if the etching selectivity of the Si substrate 10 is higher than the etching selectivity of the gate insulation film 11, the level difference between the bottom surface of the first trench 204a-1 and the bottom surface of the second trench 204a-2 becomes larger.

Instead of digging separately the first trenches 204a-1 and the second trenches 204a-2 by the lithography, trenches of different depths (first trenches 204a-1 and the second trenches 204a-2) can be formed in a single etching process. As a result, manufacturing processes can be simplified.

In addition, the top surface of the first gate insulation film 11-1 is gradually lowered towards the second gate insulation film 11-2, and is finally connected to the top surface of the second gate insulation film 11-2. Accordingly, the bottom surfaces of the first trench 204a-1 and of the second trench 204a-2 gradually deepen from the first trench 204a-1 towards the second trench 204a-2.

In the meanwhile, the device isolation trenches 304a and 404a are formed in the LV transistor region 103 and in the cell region 104, respectively. The depth of each of the device isolation trenches 304a and 404a, measured from the surface of the Si substrate 10, is substantially the same as the depth of the second trench 204a-2.

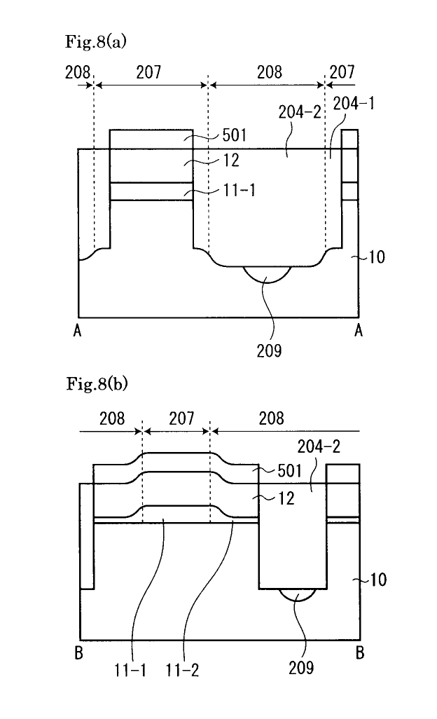

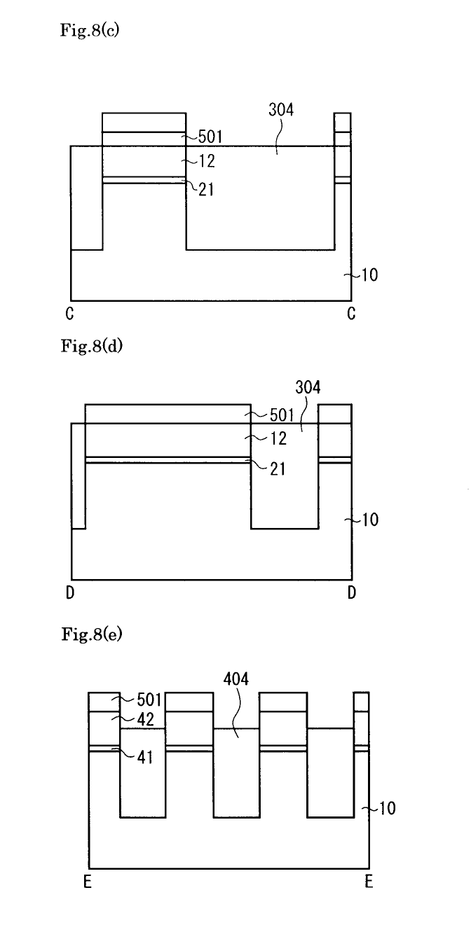

As FIGS. 8(a) to 8(e) show, the device isolation trenches 204a, 304a, and 404a are filled with insulation films, such as silicon oxide films or PSZ films, and then the filler insulation films are flattened by use of the first mask material 501 as a stopper. As a result, the device-isolation insulation films 204 HV are formed in the transistor region 102, the device-isolation insulation films 304 are formed in the LV transistor region 103, and the device-isolation insulation films 404 are formed in the cell region 104.

The first region 204-1 of the device-isolation insulation film 204 is formed in each first trench 204a-1, and the second region 204-2 of the device-isolation insulation film 204 is formed in each second trench 204a-2. P type impurities are implanted into the Si substrate 10 under the second regions 204-2 of the device-isolation insulation films 204, and thus the anti-inversion diffusion layer 209 that has a higher impurity concentration than that of the Si substrate 10 is formed.

By etching, the top surfaces of the device-isolation insulation films 204 and 304 are made to have substantially the same height as the height of the top surface of the first electrode film 12. In addition, in the cell region 104, deeper etching is performed to make the top surfaces of the device-isolation insulation films 404 lower than the top surface of the first electrode film 12.

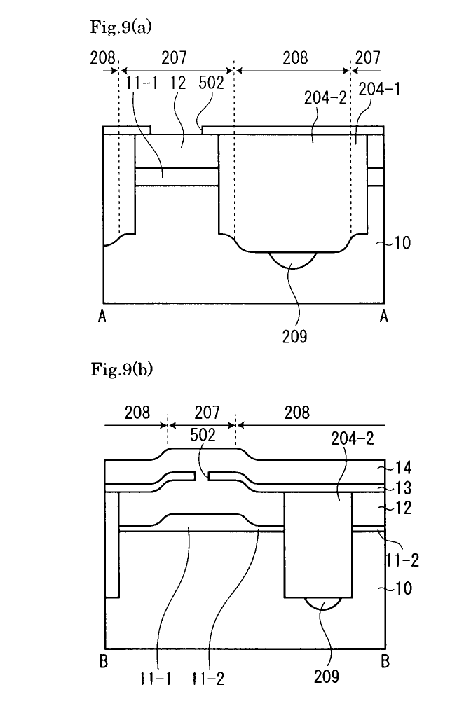

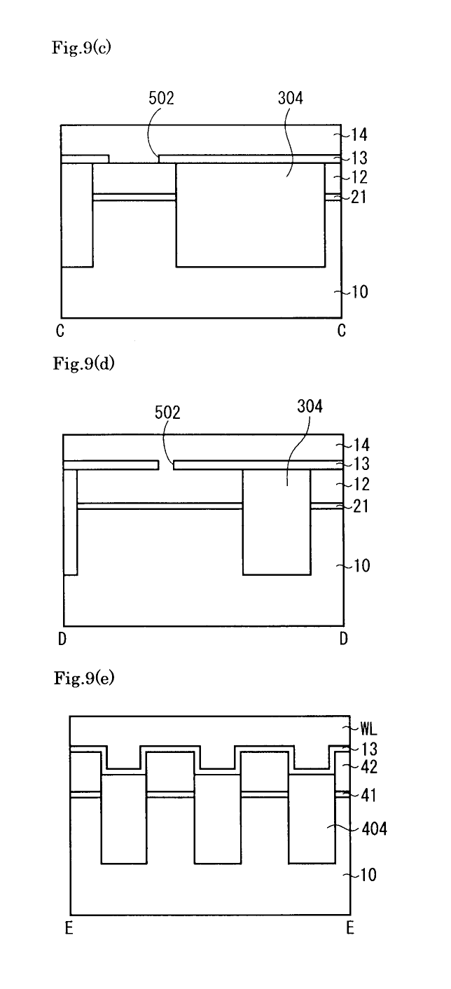

As FIGS. 9(a) to 9(e) show, after removing the first mask material 501, the gate electrodes 203 and 303 as well as the inter-gate insulation films 13 of the memory cells MC are formed by depositing a third insulation film on the entire surface. The third insulation film is removed from portions of the HV transistor region 102 and of the LV transistor region 103 so as to form openings 502. The second electrode films 14 and the control gate electrodes WL are formed by depositing a fourth electrode film on the entire surface. Thus, electrode-connection portions 210 and 310 are formed in the openings 502.

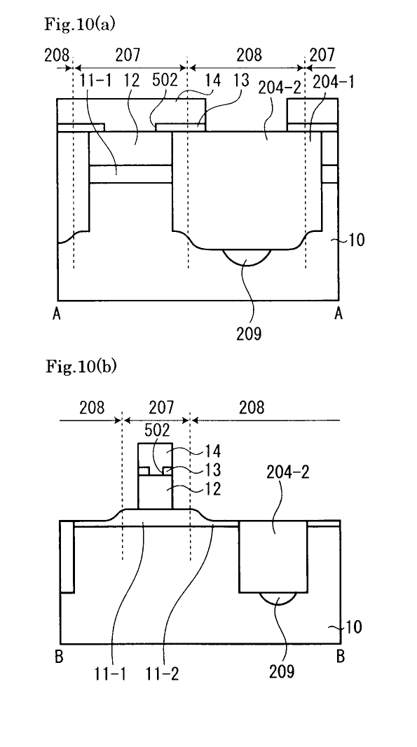

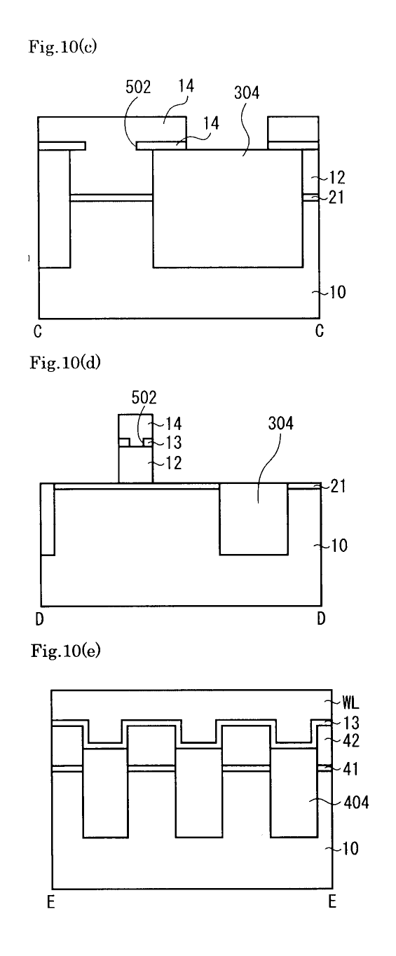

As FIGS. 10(a) to 10(e) show, by the lithography technique and the etching technique, the gate electrodes 203 of the HV transistors HV, the gate electrodes 303 of the LV transistors LV, and the gate electrodes 403 of the memory cell MC are processed (patterned).

As in shown FIGS. 2(a), 2(b), 3(a), 3(b) and 4, with the gate electrodes 203 and 303 used as a mask, N type impurities are implanted into the surface portion of the Si substrate 10 so as to form the diffusion-layer regions 18 and 19. Note that, after forming the diffusion-layer region 18a and 19a by use of the gate electrodes 203 and 303 as a mask, a spacer film (not illustrated) may be formed and then the diffusion-layer regions 18b and 19b are formed by use of the spacer film and the gate electrodes 203 and 303 as a mask.

Since the film thickness of each first gate insulation film 11-1 is larger than the film thickness of each second gate insulation film 11-2, the diffusion-layer regions 18a and 18b can be formed in a single ion-implantation process without using the spacer film by adjusting the acceleration of the ion implantation. Thus, the diffusion-layer regions 18a are formed under the first gate insulation films 11-1, and the diffusion-layer regions 18b are formed under the second gate insulation films 11-2. Note that the impurity concentration of the diffusion-layer regions 18b is higher than the impurity concentration of the diffusion-layer region 18a, and the bottom portions of the diffusion-layer regions 18b are located at a deeper level than the bottom portions of the diffusion-layer regions 18a. As a result, the manufacturing processes can be simplified.

In particular, if the HV transistors HV are P type transistors, the diffusion-layer regions 18 are formed by implanting, for example, BF₂. Note that BF₂, which has a relatively large mass, is less likely to cause expansion of each diffusion-layer region 18 by thermal diffusion. For this reason, BF₂ trapped by the first gate insulation films 11-1 is less likely to diffuse into the Si substrate 10, so that the impurity concentration of the diffusion-layer regions 18a can be decreased.

Then, by depositing, for example, a silicon oxide film on the entire surface of the Si substrate, the interlayer insulation film 23 is formed to cover the gate electrodes 203, 303, and 403. Then, gate electrode contacts 205 and 305 that are connected respectively to the gate electrodes 203 and 303 are formed by a known method.

The structure described above can achieve the following advantageous effects that are not obtainable by conventional structures.

When a voltage is applied to the gate electrode 203 of each HV transistor HV, a depletion layer is formed below the first gate insulation film 11-1 of the HV transistor. The region where the depletion layer extends is defined as a channel region. When a high voltage of 15 V or higher is applied to the gate electrode 203, the bottom of the channel region extends to the vicinity of the bottom surface of the device-isolation insulation film 204.

If, the channel region extends to the vicinity of the anti-inversion diffusion layer 209, the threshold voltage of the HV transistor is raised. The rising threshold voltage lowers the transfer voltage, which is the potential to transfer the potential of the drain to the source when the transistor is in the ON state. In particular, the lowering of the transfer voltage is a great problem in the case of the flash memories. That is, a high voltage is applied to the gate electrode WL when each memory cell is in a writing or erasing operation.

If the transfer voltage is lower, the potential generator circuit is larger in size to generate a greater potential. As a result, the semiconductor device becomes larger in size.

In the case of this embodiment, however, each device-isolation insulation film 204 in the HV transistor region 102 includes both the second region 204-2 with a depth that is substantially the same as the depth of each device-isolation insulation film 304 in the LV transistor region 103 and the first region 204-1 whose bottom surface is shallower than the bottom surface of the second region 204-2. The first region 204-1 is in contact with both the first gate insulation film 11-1 and the first electrode film 12 in the channel-width direction. In addition, the anti-inversion diffusion layer 209 is formed only under the second region 204-2 of the device-isolation insulation film 204 while anti-inversion diffusion layer 209 is not formed under the first region 204-1 of the device-isolation insulation film 204.

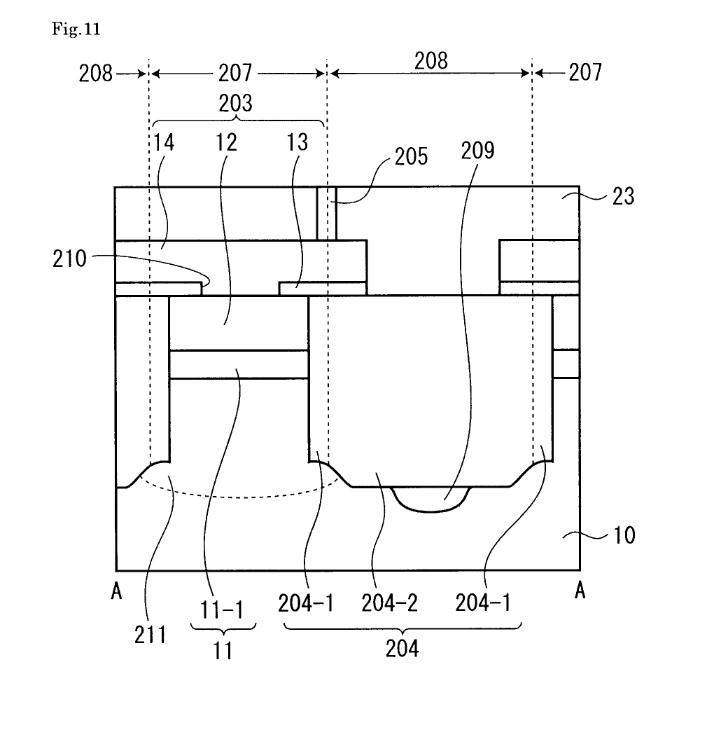

As FIG. 11 shows, if a high voltage of 15 V or higher is applied to the gate electrode 203, a channel region 211 extends to the vicinity of the bottom surface of the first region 204-1 of the device-isolation insulation film 204, but does not extend to the bottom surface of the second region 204-2. Specifically, the channel region 211 extends at most to the level-difference portion between the first region 204-1 and the second region 204-2, and is formed under the first gate electrode 12 and the first region 204-1 of the device-isolation insulation film 204.

As a result, the threshold voltage in each HV transistor HV can be prevented from rising, and no lowering of the transfer voltage occurs.

The above-described manufacturing method can achieve the following advantageous effects that are not obtainable by conventional manufacturing methods.

In the conventional manufacturing methods, the entire HV transistor region 102 is in the first region 207. As a result, the bottom surface of the device-isolation insulation film 204 in the HV transistor region 102 is at a shallower level than the bottom surface of the device-isolation insulation film 304 in the LV transistor region 103.

If the device-isolation insulation films in the HV transistor region 102 and the device-isolation insulation films in the LV transistor region 103 are formed differently from each other, the bottom surface of each device-isolation insulation film 204 in the HV transistor region 102 can be positioned at a deeper level than the bottom surface of each device-isolation insulation film 304 in the LV transistor region 103. However, the method in which the device-isolation insulation films are formed differently for these different regions requires intricate manufacturing processes.

To avoid this problem, first gate insulation films 11-1 are formed only in the first regions 207 in the HV transistor region 102. As a result, without forming different device-isolation insulation films for these different regions, each device-isolation insulation film 204 in the HV transistor region 102 can have both the second region 204-2 with substantially the same depth as the depth of each device-isolation insulation film 304 in the LV transistor region 103 and the first region 204-1 whose bottom surface is shallower than the bottom surface of the second region 204-2. Accordingly, the manufacturing processes can be simplified.

In addition, the third gate insulation film 21 of each LV transistor LV and the second gate insulation film 11-2 of each HV transistor HV can be formed simultaneously. As a result, with no additional process, each device-isolation insulation film 204 can be formed to have both the second region 204-2 and the first region 204-1 whose bottom surface is shallower than the bottom surface of the second region 204-2.

In addition, to increase the breakdown voltage of each device-isolation insulation film 204, it is preferable to make the second region 204-2 in the channel-width direction shown in FIG. 2(a) larger in size. If, however, the second region 204-2 gets too close to the device region 202, the film thickness of the first gate insulation film 11-1 on the device region 202 may possibly become closer to the film thickness of the second gate insulation film 11-2 due to the offsetting that occurs at the time of the lithography process to form the device isolation trenches shown in FIG. 7(a). Accordingly, the second region 204-2 is preferably formed as large as possible by taking account of the offsetting at the time of lithography to form the device isolation trenches and the like.

### Modified Example 1 of the First Exemplary Embodiment 1

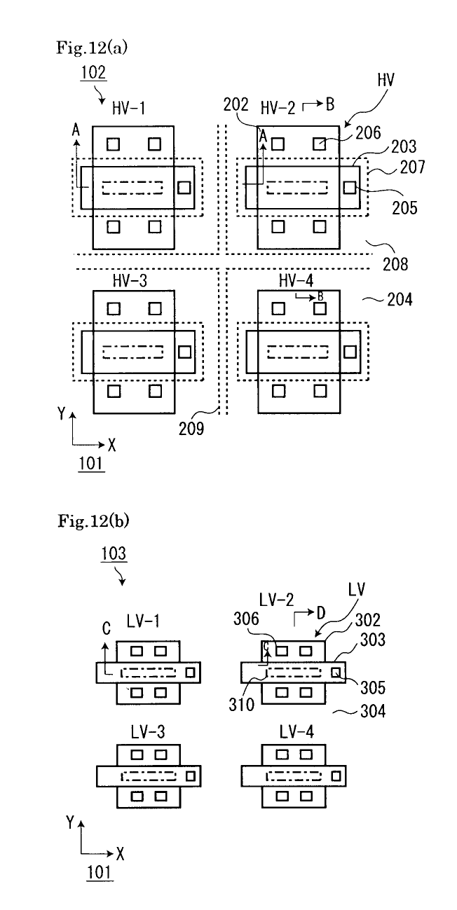

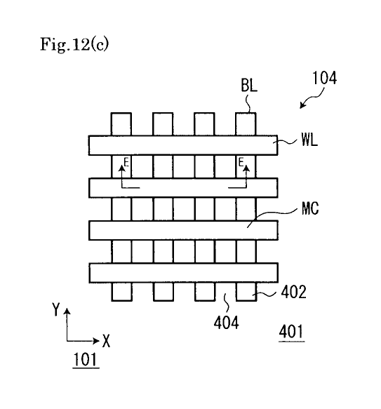

FIGS. 12(a)-12(c) show Modified Example 1 of the first exemplary Embodiment 1. FIGS. 12(a)-12(c) is a plan view corresponding to FIGS. 1(a)-1(c), and the Modified Example 1 differs from the first exemplary Embodiment 1 in the shape of the first region 207. The first region 207 of Modified Example 1 is formed to surround not only the intersecting area of the gate electrode 203 and the device region 202 but also the gate electrode 203.

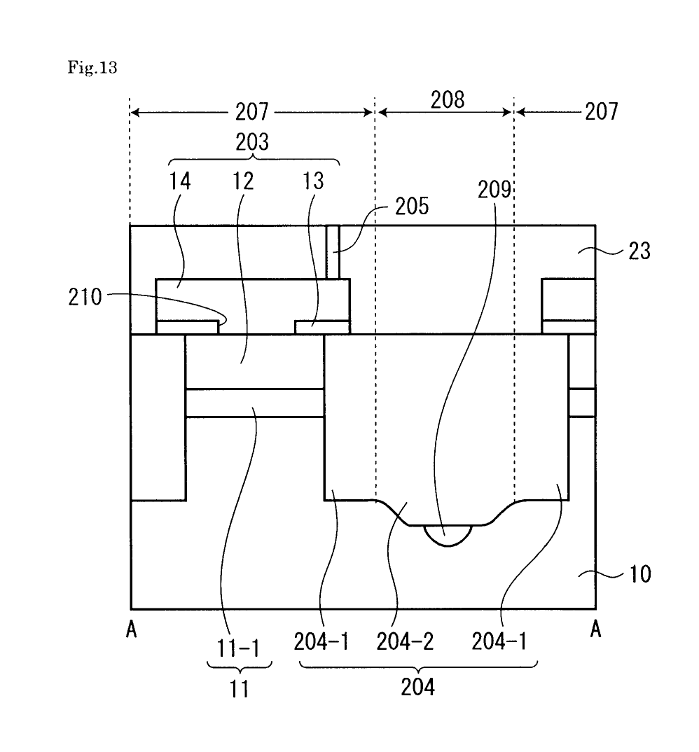

FIG. 13 is a sectional view taken along the line A-A of FIG. 12(a). As FIG. 13 shows, end portions of the gate electrode 203 are formed on the first regions 204-1 of the device-isolation insulation film 204, and the gate electrode 203 does not extend long enough to reach the second region 204-2. As a result, no electric field by the gate electrode 203 is applied from the second region 204-2. As a result, besides the effects obtained by the first exemplary Embodiment 1, the channel region 211 can be prevented effectively from extending to the anti-inversion diffusion layer 209.

### Modified Example 2 of the First Exemplary Embodiment 1

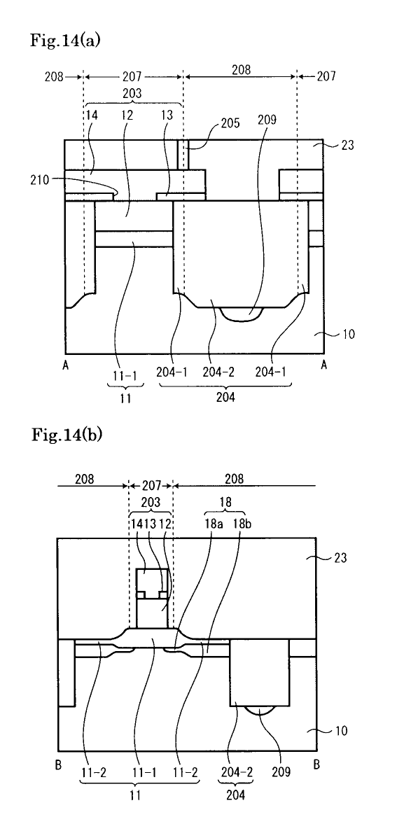

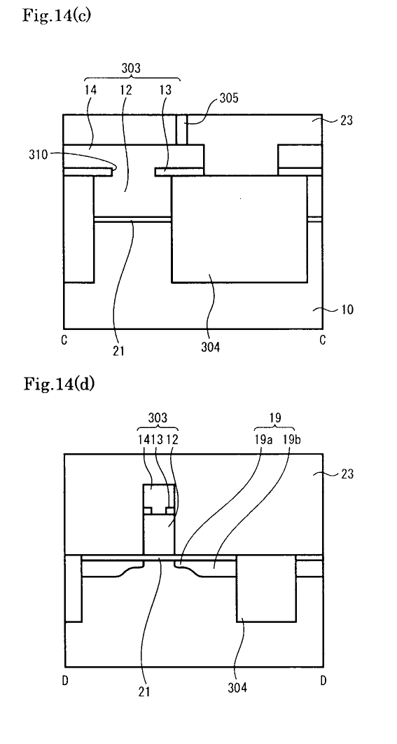

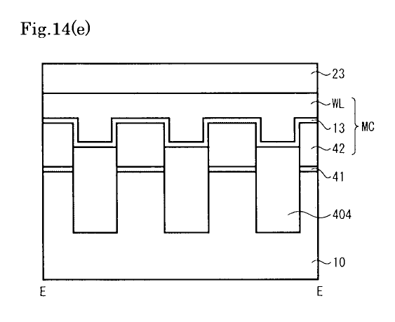

FIGS. 14(a)-14(e) show a Modified Example 2 of the first exemplary Embodiment 1. FIGS. 14(a) and 14(b) are sectional views corresponding respectively to FIGS. 2(a) and 2(b). FIGS. 14(c) and 14(d) are sectional views corresponding respectively to FIGS. 3(a) and 3(b). FIG. 14(e) is a sectional view corresponding to FIG. 4. Modified Example 2 differs from the first exemplary Embodiment 1 in the shapes of the first and the second gate insulation films 11-1 and 11-2. Note that Modified Example 2 has the same plan views as those of the first exemplary Embodiment 1. Accordingly, no plan views are given here.

As FIG. 14(b) shows, the first gate insulation film 11-1 and the second gate insulation films 11-2 whose film thickness is smaller than the film thickness of the first gate insulation film 11-1 are formed on a portion of the Si substrate 10 corresponding to the device region 202. The first gate insulation film 11-1 is formed in the first region 207, whereas the second gate insulation films 11-2 are formed in the second regions 208.

The top surface of the first gate insulation film 11-1 is higher than the top surface of each second gate insulation film 11-2, whereas the bottom surface of the first gate insulation film 11-1 is lower than the bottom surface of each second gate insulation film 11-2. In the device region 202, the gate electrode 203 is formed only on the first gate insulation film 11-1. The first gate insulation film 11-1 is connected to the second gate insulation films 11-2 so that the level of the top surface of the gate insulation film 11 changes gradually.

In addition, the top surface of the gate insulation film 21 of LV transistor LV is positioned at substantially the same level as that of the top surface of each second gate insulation film 11-2. In addition, the top surface of the tunnel insulation film 41 of each memory cell MC is positioned at substantially the same level as that of the top surface of each second gate insulation film 11-2. Accordingly, the top surfaces of the Si substrate 10 in the semiconductor device are positioned at substantially the same level except the top surface of the first region 207, and the surface of the Si substrate 10 in the second region 208 is higher than the surface of the Si substrate 10 in the first region 207.

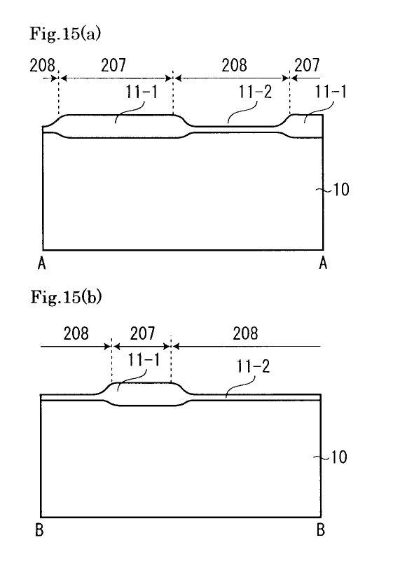

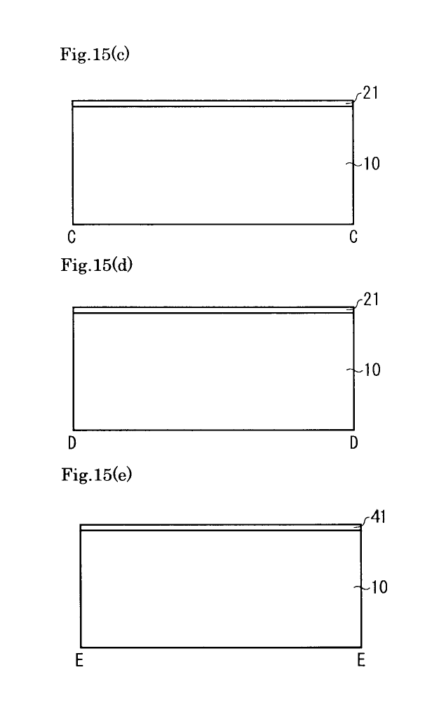

The above-described difference in the structure derives from the fact that the processing of forming the gate insulation films in Modified Example 2 is different from the corresponding processing in the first exemplary Embodiment 1. The processing of forming gate insulation film in this Modified Example 2 will be described next by referring to FIGS. 15 to 17. FIGS. 15(a) to 17(a) show sectional views corresponding to FIG. 14(a). FIGS. 15(b) to 17(b) show sectional views corresponding to FIG. 14(b). FIGS. 15(c) to 17(c) show sectional views corresponding to FIG. 14(c). FIGS. 15(d) to 17(d) show sectional views corresponding to FIG. 14(d). FIGS. 15(e) to 17(e) show sectional views corresponding to FIG. 14(e).

As FIGS. 15(a) to 15(e) show, a first silicon oxide film that is to be the gate insulation films in the HV transistors HV is formed on the entire surface of the Si substrate 10 by the thermal oxidation method so as to have a thickness of approximately 40 nm.

By the lithography technique and the etching technique, the first insulation film is removed from the LV transistor region 103, the cell region 104 and the second regions 208 in the HV transistor region 102.

By thermal oxidation method, a second insulation film is formed on the top surface of the Si substrate 10 so as to have a thickness approximately ranging from 5 nm to 10 nm. As a result, the second insulation film which is to be the gate insulation film 21 in each LV transistor LV and to be the tunnel insulation film 41 in the memory cell MC is formed so that the thickness of the second insulation film ranges from 5 nm to 10 nm. At the same time, a film thickness approximately equal to that of the second insulation film is added to the first insulation film in the HV transistor region 102. As a result, the second insulation film (second gate insulation film 11-2) is formed in regions other than first region 207, whereas the first insulation film (first gate insulation film 11-1) is formed in the first region 207 (processing of forming gate insulation film).

The top surface of each first gate insulation film 11-1 is higher than the top surface of each second gate insulation film 11-2 whereas the bottom surface of each first gate insulation film 11-1 is positioned at a deeper level than the bottom surface of each second gate insulation film 11-2. This is because, if the Si substrate 10 is oxidized by thermal oxidation method, the silicon oxide film is formed so as to extend in directions perpendicular to the Si substrate from the surface of the Si substrate 10.

A level difference is formed around the border between the first region 207 and the second region 208 of the HV transistor region 102. The top surface of the first gate insulation film 11-1 is gradually lowered towards the second region 208, and is finally connected to the top surface of the second gate insulation film 11-2

The top surface of the Si substrate in each second region 208 located in the HV transistor region 102, the top surface of the Si substrate in the LV transistor region 103, and the top surface of the Si substrate in the cell region 104 are at the same level. Accordingly, the top surfaces of the second gate insulation films 11-2 in the HV transistor region 102, the top surfaces of the gate insulation films 21 of the LV transistors LV, and the top surfaces of tunnel insulation films 41 of the memory cells MC are substantially at the same level.

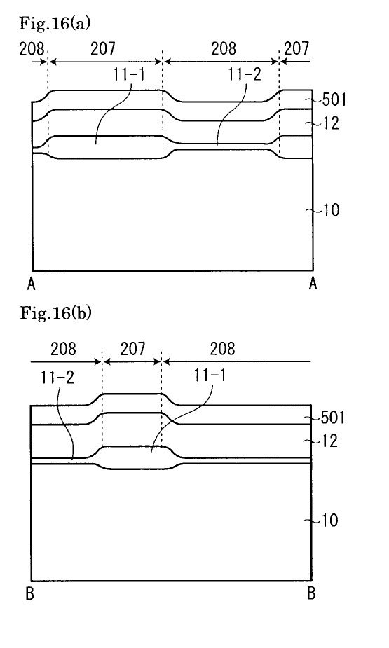

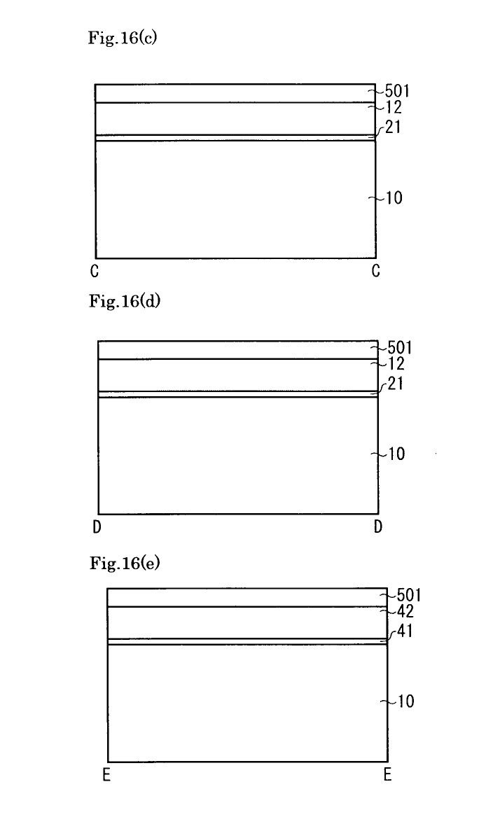

After the processes that are similar to those performed in the first exemplary Embodiment 1, the state shown in FIGS. 16(a)-16(e), which is the state before the process of forming device isolation trenches, is achieved. Concerning the top surface of the first mask material 501 in the HV transistor region 102, the portion of the top surface above each of the second gate insulation films 11-2 is lower than the portion of the top surface above the first gate insulation film 11-1. In addition, in the HV transistor region 102, the laminate structure of each first region 207 and the laminate structure of each second region 208 are basically the same except that the film thicknesses of the first and the second gate insulation films 11-1 and 11-2 are different.

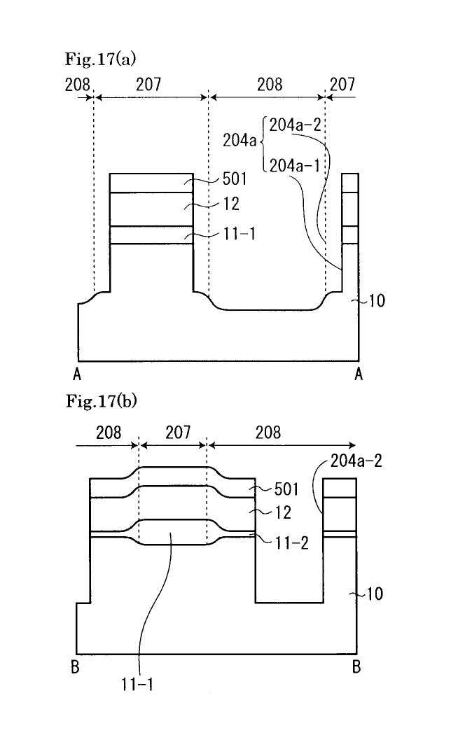

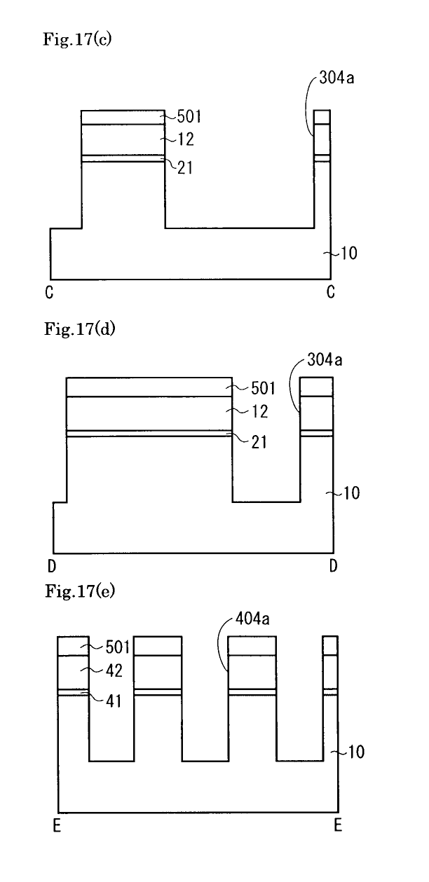

As FIGS. 17(a)-17(e) show, the layered structure of the HV transistor region 102 is etched at a single etching process. As a result, both a second trench 204a-2 and a first trench 204a-1 that has a shallow bottom surface than the bottom surface of the second trench 204a-2 are formed in the device isolation trench 204a in the HV transistor region 102 as in the case of the first exemplary Embodiment 1.

Even if the bottom surface of the first gate insulation film 11-1 is positioned at a deeper level than that of the bottom surface of the second gate insulation film 11-2, the film thickness of the first gate insulation film 11-1 in the first region 207 is larger than the film thickness of the second gate insulation film 11-2. As a result, the depth measured from the bottom surface of the first gate insulation film 11-1 is larger in the second trench 204a-2 than in the first trench 204a-1.

In addition, as in the case of the first exemplary Embodiment 1, the top surface of the first gate insulation film 11-1 is gradually lowered towards each of the second regions 208, and is finally connected to the top surface of each second gate insulation film 11-2. Accordingly, the bottom surfaces of the first trench 204a-1 and the second trench 204a-2 gradually deepen from the first trench 204a-1 towards the second trench 204a-2.

In the meanwhile, the device isolation trenches 304a and 404a are formed in the LV transistor region 103 and in the cell region 104, respectively. The depth of each of the device isolation trenches 304a and 404a, measured from the bottom surface of the first gate insulation film 11-1, is substantially the same as the depth of the second trench 204a-2.

After the processes that are similar to those performed in the first exemplary Embodiment 1, the structure shown in FIGS. 14(a) to 14(e) is produced. Similar effects to those obtainable by the first exemplary Embodiment 1 can be obtained by this Modified Example, as well. In addition, Modified Example 2 is also applicable to the structure of Modified Example 1 of the first exemplary Embodiment 1.

### Secondary Exemplary Embodiment 2

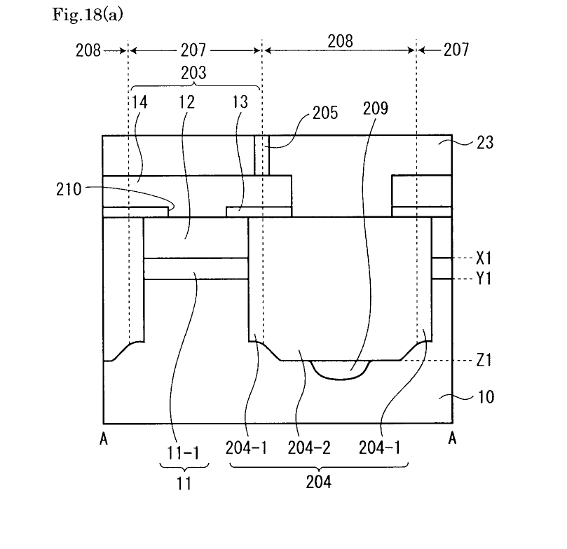

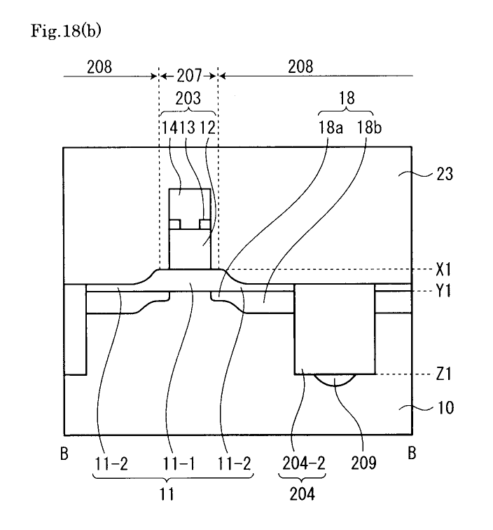

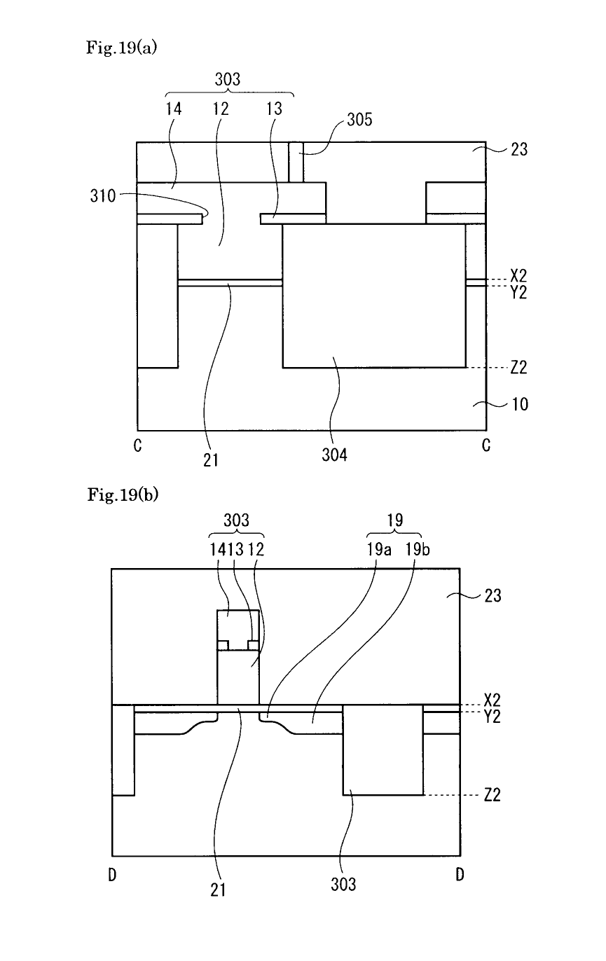

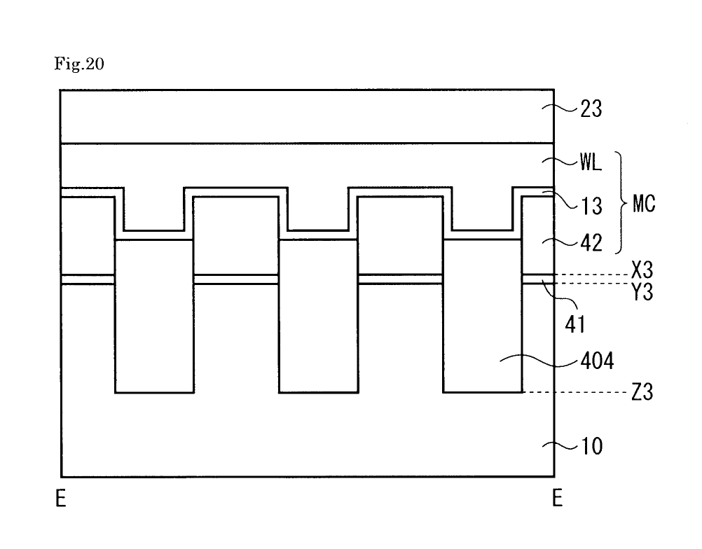

FIGS. 18(a)-18(b) show the second exemplary Embodiment 2. FIGS. 18(a) and 18(b) are sectional views corresponding respectively to FIGS. 2(a) and 2(b). FIGS. 19(a) and 19(b) are sectional views corresponding respectively to FIGS. 3(a) and 3(b). FIG. 20 is a sectional view corresponding to FIG. 4. The second exemplary Embodiment 2 differs from the first exemplary Embodiment 1 in the position of the top surfaces of the gate insulation films of the LV transistors LV. Note that the second exemplary Embodiment 2 has the same plan views as those of the first exemplary Embodiment 1. Accordingly, no plan views are given here.

As FIGS. 18(a) and 18(b) show, the position of the top surface of the first gate insulation film 11-1 in the HV transistor region 102 is denoted by X1. As FIGS. 19(a) and 19(b) show, the position of the top surface of the gate insulation film 21 in the LV transistor region 102 is denoted by X2. As FIG. 20 shows, the position of the top surface of the tunnel insulation film 41 in the memory cell MC is denoted by X3. In this second exemplary Embodiment 2, the positions X1 to X3 are at substantially the same level.

Accordingly, the position of the top surface of the gate electrode 203 in each HV transistor HV, the position of the top surface of the gate electrode 303 in each LV transistor LV, and the position of the top surface of each word line WL can be at substantially the same level. Accordingly, the process margin of the gate electrode processing can be improved. In addition, the position of the top surface of each second gate insulation film 11-2 is at a lower level than both the position of the top surface of the gate insulation film 21 in each LV transistor LV and the position of the top surface of each tunnel insulation film 41.

The position of the top surface of the Si substrate 10 in the HV transistor region 102 is denoted by Y1. In addition, as FIGS. 19(a), 19(b), and 20 show, the position of the top surface of the Si substrate 10 in the LV transistor region 103 is denoted by Y2 and the position of the top surface of the Si substrate 10 in the cell region 104 is denoted by Y3. Note that the position Y1 is lower than both of the positions Y2 and Y3.

The position of the bottom surface of each second device-isolation insulation film 204-2 in the HV transistor region 102 is denoted by Z1. As FIGS. 19(a), 19(b), and 20 show, the position of the bottom surface of each device-isolation insulation film 304 in the LV transistor region 103 is denoted by Z2 and the position of the bottom surface of each device-isolation insulation film 304 in the cell region 104 is denoted by Z3. The position measured from the surface of the Si substrate 10 is at a deeper level in the cases of the positions Z2 and Z3 than in the case of the position Z1.

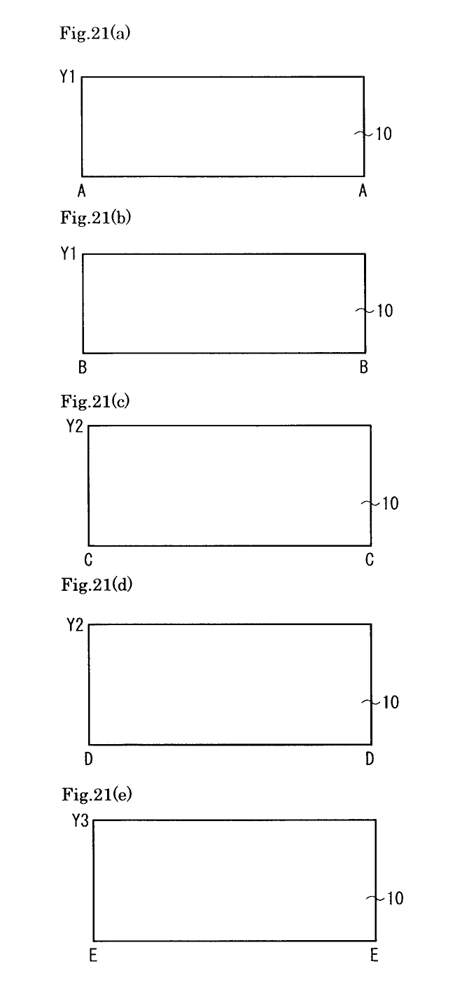

The above-mentioned difference in structure derives from the fact that the manufacturing method in this second exemplary Embodiment 2 differs from the manufacturing method of the first exemplary Embodiment 1. The processing of forming gate insulation film in this second exemplary Embodiment 2 will be described next by referring to FIGS. 21 to 24. FIGS. 21(a) to 24(a) show sectional views corresponding to FIG. 5(a). FIGS. 21(b) to 24(b) show sectional views corresponding to FIG. 5(b). FIGS. 21(c) to 24(c) show sectional views corresponding to FIG. 5(c). FIGS. 21(d) to 24(d) show sectional views corresponding to FIG. 5(d). FIGS. 21(e) to 24(e) show sectional views corresponding to FIG. 5(e).

As FIGS. 21(a) to 21(e) show, the top surface of the Si substrate 10 corresponding to the HV transistor region 102 is etched so that the gate electrode 203 of each HV transistor HV, the gate electrode 303 of each LV transistor LV, and the gate electrode 403 of each memory cell MC have the same height.

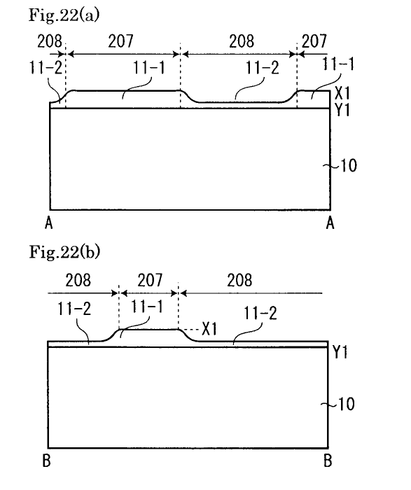

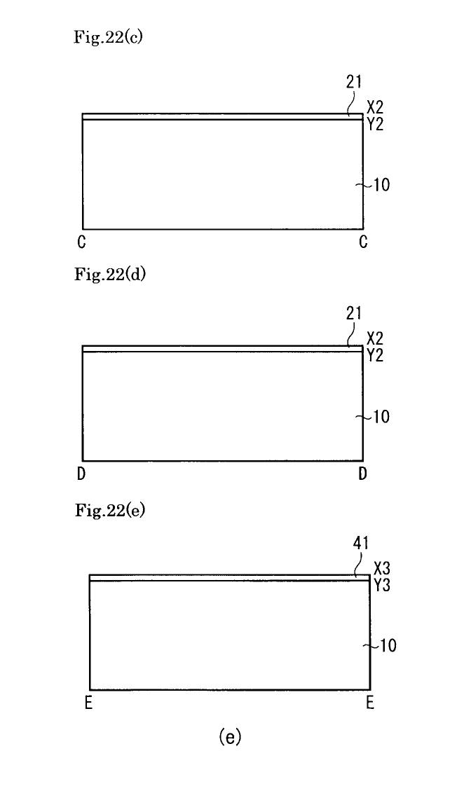

As FIGS. 22(a) to 22(e) show, a first insulation film that is to be the gate insulation films in the HV transistors HV is formed on the entire surface of the Si substrate 10 by the thermal oxidation method so as to have a thickness of approximately 40 nm.

By, for example, the lithography technique and the etching technique, the first insulation film is removed from the LV transistor region 103, the cell region 104 and the second regions 208 in the HV transistor region 102.

By, for example, the CVD method, a second insulation film is formed on the top surface of the Si substrate 10 so as to have a thickness approximately ranging from 5 nm to 10 nm. As a result, the second insulation film which is to be the gate insulation film 21 in each LV transistor LV and to be the tunnel insulation film 41 in the memory cell MC is formed so that the thickness of the second insulation film ranges from 5 nm to 10 nm. At the same time, the second insulation film is formed also in the HV transistor region 102, so that the second insulation film (second gate insulation film 11-2) is formed in the second region 208, and a laminate film (first gate insulation film 11-1) including both the first insulation film and the second insulation film is formed in the first region 207 (process of forming gate insulation film).

A level difference caused by the difference in film thickness between the first gate insulation film 11-1 and the second gate insulation film 11-2 is formed around the border of the first region 207 in the HV transistor region 102. The level difference is so formed that the top surface of the first gate insulation film 11-1 is gradually lowered towards the second region 208, and is finally connected to the top surface of the second gate insulation film 11-2.

The top surface of each first gate insulation film 11-1 in the HV transistor region 102, the top surface of each gate insulation film 21 in the LV transistor region 103, and the top surface of each tunnel insulation film 41 in the cell region 104 are at substantially the same level. Accordingly, the top surface of each second gate insulation film 11-2 in HV transistor region 102 is positioned at a lower level than the top surface of each first gate insulation film 11-1 in the HV transistor region 102, the top surface of each gate insulation film 21 in the LV transistor region 103, and the top surface of each tunnel insulation film 41 in the cell region 104. In addition, the top surface of the Si substrate 10 is higher in the LV transistor region 103 and in the cell region 104 than in the HV transistor region 102.

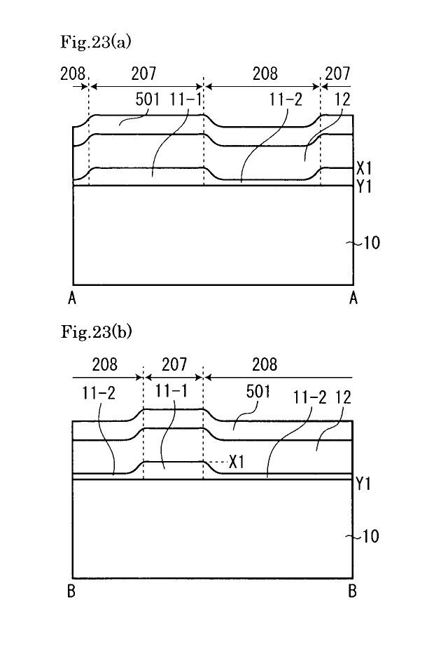

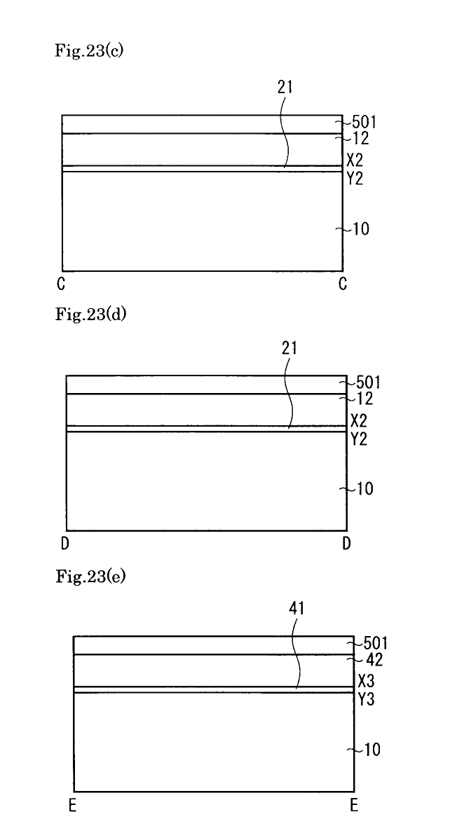

As FIGS. 23(a) to 23(e) show, the first electrode film is deposited on the entire surface so as to form both the floating gate electrodes 42 of the memory cells MC and the first electrode films 12. The first mask material 501 to form device-isolation insulation films 204, 304, and 404 is deposited on the first electrode film so as to have a certain film thickness. As a result, in the HV transistor region 102, the top surface of the first mask material 501 has a shape that traces the top surfaces of the first and the second gate insulation films 11-1 and 11-2.

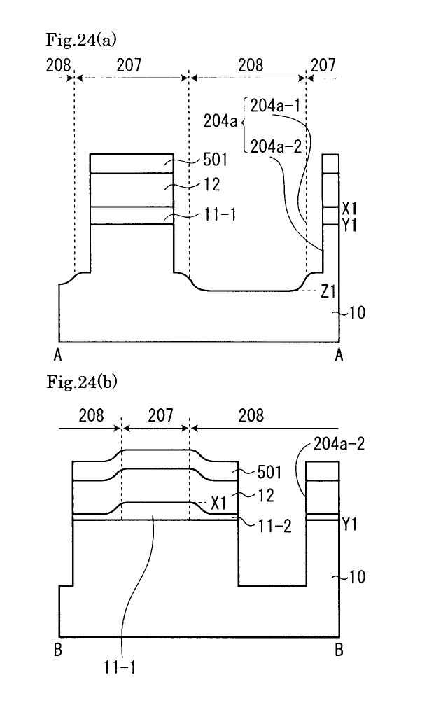

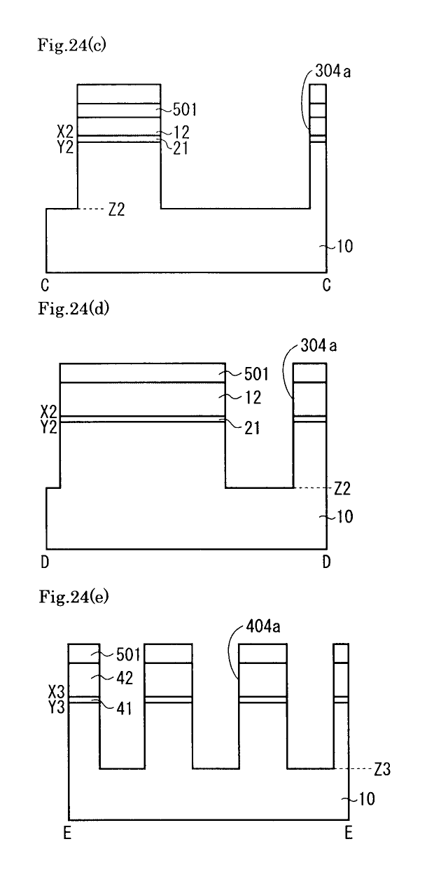

As FIGS. 24(a) to 24(e) show, a resist mask having openings at the regions where device-isolation insulation films 204, 304, and 404 are to be formed is formed by lithography. By the etching technique, device-isolation trenches 204a, 304a, and 404a where the device-isolation insulation films 204, 304, and 404 are to be formed by are formed at a single process (device-isolation trench forming process). The top surface of the first mask material 501 in the HV transistor region 102 is formed so that the portions of the top surfaces above the first gate insulation films 11-1 are higher than the portions thereof above the second gate insulation films 11-2. In addition, in the HV transistor region 102, the laminate structure of the first region 207 and the laminate structure of the second region 208 are basically the same except that the film thicknesses of the first and the second gate insulation films 11-1 and 11-2 are different.

By the single etching the layered structure of the HV transistor region 102, a second trench 204a-2 and first trenches 204a-1 each of which has a shallower bottom surface than the bottom surface of the second trench 204a-2 are formed in each device isolation trench 204a located in the HV transistor region 102. Since the film thickness of the first gate insulation film 11-1 in the first region 207 is larger than the film thickness of the second gate insulation film 11-2, the depth measured from the surface of the Si substrate 10 is larger in the second trench 204a-2 than in the first trench 204a-1.

The difference in level between the bottom surface of the first trench 204a-1 and the bottom surface of the second trench 204a-2 can be adjusted by changing the etching selectivity of each of the gate insulation film 11 and the Si substrate 10. For example, if the etching selectivity of the Si substrate 10 is higher than the etching selectivity of the gate insulation film 11, the level difference between the bottom surface of the first trench 204a-1 and the bottom surface of the second trench 204a-2 becomes larger.

Instead of digging separately the first trenches 204a-1 and the second trenches 204a-2 by lithography, trenches of different depths (first trenches 204a-1 and the second trenches 204a-2) can be formed in a single etching process. As a result, manufacturing processes can be simplified.

In addition, the top surface of the first gate insulation film 11-1 is gradually lowered towards the second region 208, and is finally connected to the top surface of the second gate insulation film 11-2. Accordingly, the bottom surfaces of the first trench 204a-1 and of the second trench 204a-2 gradually deepen from the first trench 204a-1 towards the second trench 204a-2.

In the meanwhile, the device isolation trenches 304a and 404a are formed in the LV transistor region 103 and in the cell region 104, respectively. The top surface of the Si substrate 10 is higher both in the LV transistor region 103 and in the cell region 104 than the top surface of the Si substrate 10 in the HV transistor region 102. As a result, the depth of each of the device isolation trenches 304a and 404a, measured from the surface of the Si substrate 10, is smaller than the depth of the device isolation trench 204a-2.

After the processes that are similar to those performed in the first exemplary Embodiment 1, the semiconductor memory device shown in FIGS. 18 to 20 can be manufactured.

According to the structure and the manufacturing method described above, not only can similar effects to those obtainable by the first exemplary Embodiment 1 be obtained but also crystal defects of the LV transistor LV can be avoided.

For example, if the device-isolation insulation films 304 are insulation films with a large contraction stress, such as polysilazane (PSZ), the stress causes crystal defects in the LV transistors LV, and thus the LV transistors LV may be broken. It is known that the breakage caused by the crystal defects does not occur if the volume of the PSZ is small.

In this second exemplary Embodiment 2, the bottom surface of each device-isolation insulation film 304 in the LV transistor region 103 can be positioned at a shallower level. As a result, the breakage of the device caused by crystal defects can be prevented effectively.

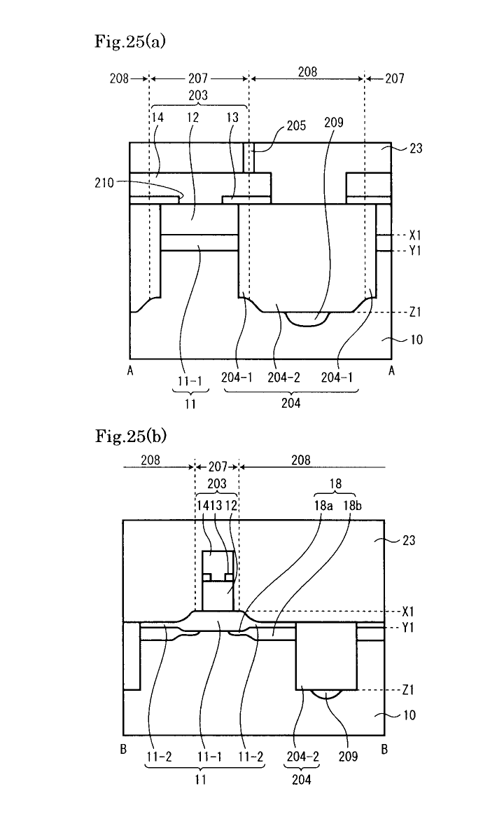

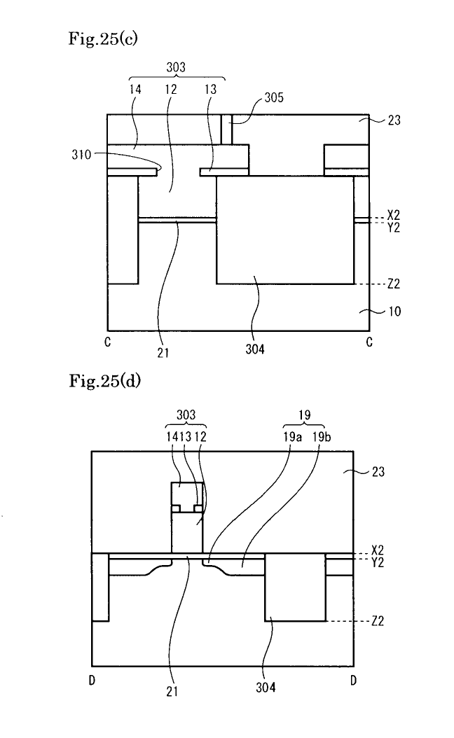

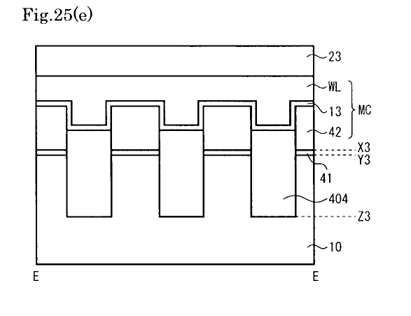

In addition, Modified Examples 1 and 2 of the first exemplary Embodiment 1 are applicable to this second exemplary Embodiment 2. A case of applying Modified Example 2 of the first exemplary Embodiment 1 to the second exemplary Embodiment 2 will be described below by referring to FIGS. 25(a)-25(e).

As FIGS. 25(a)-25(e) show, in addition to the second exemplary Embodiment 2, the top surface of each first gate insulation film 11-1 is higher than the top surface of each second gate insulation film 11-2, whereas the bottom surface of each first gate insulation film 11-1 is positioned at a deeper level than the bottom surface of each second gate insulation film 11-2. The gate electrode 203 is formed only above the first gate insulation film 11-1. The first gate insulation film 11-1 is connected to the second gate insulation films 11-2 so that the top surface of the insulation film 11 changes gradually in level.

As a result, not only the advantageous effects obtainable by the second exemplary Embodiment 2 but also the advantageous effects obtainable by Modified Example 2 of the first exemplary Embodiment 1 can be obtained.

Note that the description of the above-described embodiments is based on cases of NAND flash memories. The exemplary embodiments, however, is not limited to such cases. The exemplary embodiments are similarly applicable to various kinds of semiconductor devices in which device-isolation structure in the LV transistor region differs from the device-isolation structure in the HV transistor region.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A semiconductor device comprising:
a semiconductor substrate;
a first device-isolation insulation film that divides the semiconductor substrate at a first transistor region into first device regions;
a second device-isolation insulation film that divides the semiconductor substrate at a second transistor region into second device regions;
a plurality of first transistors formed in the first transistor region;
a plurality of second transistors formed in the second transistor region; and
an anti-inversion diffusion layer formed under the first device-isolation insulation film, wherein
each of the first transistors includes:
a first gate insulation film provided on the first device region;
a first gate electrode provided on the first gate insulation film and extending on the first device-isolation insulation film; and
a first diffusion layer formed on a surface of the semiconductor substrate so as to sandwich the first gate electrode;
each of the second transistors includes:
a second gate insulation film provided on the second device region and having a smaller film thickness than the first gate insulation film;
a second gate electrode provided on the second gate insulation film; and
a second diffusion layer formed on the surface of the semiconductor substrate so as to sandwich the second gate electrode;
the first device-isolation insulation film includes:
a first region that is adjacent to the first device region; and
a second region whose bottom portion is located at a deeper level than a bottom portion of the first region; and
the anti-inversion diffusion layer is formed under the second region of the first device-isolation insulation film.

2. The semiconductor device according to claim 1, wherein a channel region of each of the first transistors is formed under the first gate electrode and the first region of the first device-isolation insulation film.

3. The semiconductor device according to claim 1, wherein an end portion of the first gate electrode is formed on the first region of the first device-isolation insulation film.

4. The semiconductor device according to claim 1, wherein
each of the first transistors further includes a third gate insulation film that is adjacent to the first gate insulation film, and
the third gate insulation film has a same film thickness as the second gate insulation film.

5. The semiconductor device according to claim 4, wherein the first gate insulation film and the third gate insulation film are connected to each other so that a top surface of the first gate insulation film changes gradually at a border between top surfaces of the first and third gate insulation films.

6. The semiconductor device according to claim 4, wherein
the first diffusion layer includes a first portion and a second portion whose bottom portion is located at a shallower depth than that of the first portion, and
the second portion is formed under the first gate insulation film.

7. The semiconductor device according to claim 4, wherein a bottom portion of the first gate insulation film is located at a deeper level than a bottom portion of the third gate insulation film.

8. The semiconductor device according to claim 4, wherein the first region and the second region are connected to each other so that a bottom surface of the first region changes gradually at a border between the first region and the second region.

9. The semiconductor device according to claim 1, wherein in a direction orthogonal to a direction in which the first gate electrode extends, a width of the first gate electrode is smaller than a width of the first gate insulation film.

10. A method of manufacturing a semiconductor device comprising:
forming a first gate insulation film on a semiconductor substrate in a first region of a first transistor region;
forming a second gate insulation film on the semiconductor substrate in a second region of the first transistor region and in a second transistor region, the second gate insulation film having a smaller film thickness than the first gate insulation film, and the second region surrounding the first region;
etching the first gate insulation film, the second gate insulation film, and the semiconductor substrate, and thereby forming a first trench in the first region of the first transistor region, forming a deeper second trench than the first trench in the second region of the first transistor region, and forming a third trench in the second transistor region;
filling the first trench and the second trench with an insulation film, thereby forming a first device-isolation insulation film;
filling the third trench with an insulation film, thereby forming a second device-isolation insulation film;
forming an anti-inversion diffusion layer under the second trench of the first device-isolation insulation film;
forming a first gate electrode on the first gate insulation film of the first transistor region, and forming a second gate electrode on the second gate insulation film of the second transistor region; and
forming a diffusion layer by using the first gate electrode and the second gate electrode as a mask.

11. The method of manufacturing a semiconductor device according to claim 10, further comprising:
etching a top surface of the semiconductor substrate in the first transistor region, before the forming the first gate insulation film, to make a top surface of the first gate insulation film in the first transistor region located at a same level as a top surface of the second gate insulation film in the second transistor region, and to make the top surface of the second gate insulation film located at a lower level than the top surface of the first gate insulation film in the first transistor region, wherein
the third trench is shallower than the second trench.

12. The method of manufacturing a semiconductor device according to claim 10, wherein, in the forming the diffusion layer, an extension region and a high-concentration region with a higher impurity concentration than an impurity concentration of the extension region are formed, in a self-aligned manner, respectively in the first portion and in the second portion.

13. The method of manufacturing a semiconductor device according to claim 10, wherein the forming the first gate insulation film is performed by a thermal oxidation method.

14. The method of manufacturing a semiconductor device according to claim 13, wherein the forming the second gate insulation film is performed by a thermal oxidation method.

15. The method of manufacturing a semiconductor device according to claim 10, wherein the forming the first trench and the second trench is performed under a condition that an etching selectivity of the semiconductor substrate is higher than both an etching selectivity of the first gate insulation film and an etching selectivity of the second gate insulation film.

16. The method of manufacturing a semiconductor device according to claim 10, further comprising:
forming a conductive film both on the first gate insulation film and on the second gate insulation film after the first gate insulation film and the second gate insulation film are formed, wherein
a position of a top surface of the conductive film in the first region is higher than a position of a top surface of the conductive film in the second region.

17. The method of manufacturing a semiconductor device according to claim 16, wherein the first gate electrode and the second gate electrode are formed by processing the conductive film.
